(19) United States
(12) Patent Application Publication
(10) Pub. No.: US 2025/0307492 A1
(43) Pub. Date: Oct. 2, 2025

(54) VIRTUAL INTERACTIVE MICROSCOPE EXPERIMENT SIMULATION PLATFORM

(71) Applicant: FEI Company, Hillsboro, OR (US)

(72) Inventors: Dennis Vymer, Svetla (CZ); Lukás Hübner, Jiríkovice (CZ); Martin Hanák, Brno (CZ); Pavel Gos, Vysoká (CZ)

(21) Appl. No.: 18/616,952

(22) Filed: Mar. 26, 2024

(51) Int. Cl. G06F 30/20

(52) U.S. Cl. CPC G06F 30/20

(57) ABSTRACT

Embodiments herein relate to a process for imaging device virtual simulation. A system can comprise a memory that stores, and a processor that executes, computer executable components. The computer executable components can comprise a rendering engine component that renders a virtual environment comprising a three-dimensional simulation of a simulated imaging device comprising a simulated chamber having a simulated object for analysis being rendered therein; and a simulating component that generates simulation data corresponding to a directed interaction comprising a three-dimensional modification of the simulated object.

### BACKGROUND

Scientific instruments for use in material analysis can aid in determining the makeup and properties of an unknown composition. Training for, setting up for and operating experiments on such scientific instruments can comprise complex processes and/or interactions.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1 illustrates a block diagram of an example scientific instrument for performing operations, in accordance with one or more embodiments described herein.

FIG. 2 illustrates a flow diagram of an example method of performing operations using the scientific instrument of FIG. 1, in accordance with one or more embodiments described herein.

FIG. 3 illustrates a graphical user interface (GUI) that can be used in the performance of one or more of the methods described herein, in accordance with one or more embodiments described herein.

FIG. 4 illustrates a block diagram of an example computing device that can perform one or more of the methods disclosed herein, in accordance with one or more embodiments described herein.

FIG. 5 illustrates a block diagram of an example, non-limiting system that can facilitate a process for imaging device virtual simulation, in accordance with one or more embodiments described herein.

FIG. 6 illustrates a block diagram of another example, non-limiting system that can facilitate a process for imaging device virtual simulation, in accordance with one or more embodiments described herein.

FIG. 7 provides a block diagram of an imaging system, in accordance with one or more embodiments described herein.

FIG. 8 provides another block diagram of the non-limiting system of FIG. 6, in accordance with one or more embodiments described herein.

FIG. 9 illustrates a schematic diagram of generation of a virtual environment by the non-limiting system of FIG. 6, in accordance with one or more embodiments described herein.

FIG. 10 illustrates a set of images that can be generated by the non-limiting system of FIG. 6, in accordance with one or more embodiments described herein, where the set of images illustrates various interactions and/or digital displays that can be generated by the non-limiting system of FIG. 6.

FIG. 11 illustrates another set of images that can be generated by the non-limiting system of FIG. 6, in accordance with one or more embodiments described herein, where the set of images illustrates various interactions and/or digital displays that can be generated by the non-limiting system of FIG. 6.

FIG. 12 illustrates still another set of images that can be generated by the non-limiting system of FIG. 6, in accordance with one or more embodiments described herein, where the set of images illustrates various different parameterizations that can be employed for the virtual environment by the non-limiting system of FIG. 6.

FIG. 13 illustrates flow diagram of one or more processes that can be performed by the non-limiting system of FIG. 6, in accordance with one or more embodiments described herein.

FIG. 14 illustrates flow diagram of one or more processes that can be performed by the non-limiting system of FIG. 6, in accordance with one or more embodiments described herein.

FIG. 15 illustrates a continuation of the flow diagram of FIG. 14 of the one or more processes that can be performed by the non-limiting system of FIG. 6, in accordance with one or more embodiments described herein.

FIG. 16 illustrates a block diagram of example scientific instrument system in which one or more of the methods described herein can be performed, in accordance with one or more embodiments described herein.

FIG. 17 illustrates a block diagram of an example operating environment into which embodiments of the subject matter described herein can be incorporated.

FIG. 18 illustrates an example schematic block diagram of a computing environment with which the subject matter described herein can interact and/or be implemented at least in part.

### SUMMARY

The following presents a summary to provide a basic understanding of one or more embodiments described herein. This summary is not intended to identify key or critical elements, and/or to delineate scope of particular embodiments or scope of claims. Its sole purpose is to present concepts in a simplified form as a prelude to the more detailed description that is presented later. In one or more embodiments, systems, computer-implemented methods, apparatuses and/or computer program products described herein can provide process for imaging device virtual simulation, such as for any one or more purposes of training, learning, coding, experimenting and/or predicting use of a non-virtually-simulated imaging device, without being limited thereto. For example, such imaging device can comprise an electron microscope (EM), such as a scanning electron microscope (SEM) or transmission electron microscope (TEM), and/or a focused ion beam (FIB) device.

In accordance with an embodiment, a system can comprise a memory that stores computer executable components, and a processor that executes the computer executable components. The computer executable components can comprise a rendering engine component that renders a virtual environment comprising a three-dimensional simulation of a simulated imaging device comprising a simulated chamber having a simulated object for analysis being rendered therein; and a simulating component that generates simulation data corresponding to a directed interaction comprising a three-dimensional modification of the simulated object.

In accordance with another embodiment, a computer-implemented method can comprise rendering, by a system operatively coupled to a processor, a virtual environment comprising a three-dimensional simulation of a simulated imaging device comprising a simulated chamber having a simulated object for analysis being rendered therein; and generating, by the system, simulation data corresponding to a digital display of an interaction comprising a three-dimensional modification of the simulated object.

In accordance with still another embodiment, a computer program product facilitating a process for imaging device virtual simulation can comprise a computer readable storage medium having program instructions embodied therewith, the program instructions executable by a processor to render, by the processor, a virtual environment comprising a three-dimensional simulation of a simulated object within a simulated chamber of a simulated imaging device; and generate, by the processor, simulation data corresponding to a digital display of an interaction comprising a three-dimensional modification of the simulated object.

The one or more embodiments disclosed herein can allow for ability to learn, train on, study, experiment with and/or otherwise employ imaging device techniques with or without the use of the respective imaging device (also herein referred to as a non-virtually-simulated (NVS) imaging device or a real-world imaging device). Interactions within the simulated chamber provided by the one or more embodiments described herein can allow for modification of a simulated sample (e.g., sample grid, lamella, etc.), movement of a simulated sample, work on a simulated sample with a simulated tool, etc., while simulating precise and/or repetitive movement conditions of the respective imaging device. Indeed, the one or more embodiments described herein can be employed to test control software or code while providing notification of work process failure or touch alarms, among other notifications, without the use of a respective imaging device.

The one or more embodiments described herein can allow for use of a set of controls being at least partially the same as, and/or replicating, a device set of controls of the non-virtually-simulated imaging device. In this way, a method and/or technique of using a NVS imaging device can be directly employed with the simulated imaging device as generated by the one or more embodiments described herein.

In one or more cases, the one or more embodiments described herein can be employed in conjunction with (e.g., communicatively coupled to) an automation and/or control (AAC) component that is otherwise employed to automate and/or control a NVS imaging device. In such cases, back and forth feedback can be provided between the one or more embodiments described herein, regarding the simulation, and the AAC component. That is, this back-and-forth feedback can be employed in place of existing back and forth feedback between a NVS imaging device server and the AAC component.

Accordingly, the AAC component can provide input to the one or more embodiments described herein to control a respective simulation in place of the AAC component controlling the NVS imaging device. Likewise, the one or more embodiments described herein can provide output as feedback to the AAC component, in place of receipt of feedback at the AAC component from a NVS imaging device server. That is, the AAC component can interpret the feedback from the one or more embodiments as feedback from a NVS imaging device.

In connection with the above, the one or more embodiments described herein can provide for parameterization within a simulated environment that replicates, and/or is similar to, available parameterization of a NVS imaging device. Parameters that can be simulated by the one or more embodiments described herein can comprise, but are not limited to, lighting, imaging voltage and/or resultant image noise. Furthermore, such parameters can comprise error injection parameters, such as to simulate one or more flaws of physical hardware of a NVS imaging device, such as, but not limited to, image drift and/or blurring.

Further, in one or more cases, the one or more embodiments described herein can be employed in connection with execution at a NVS imaging device (e.g., setup, test, experiment, etc.). For example, a simulated interaction generated by the one or more embodiments described herein can allow for a simulated test of a subsequent action to be performed at the NVS imaging device.

### DETAILED DESCRIPTION

The following detailed description is merely illustrative and is not intended to limit embodiments and/or application or utilization of embodiments. Furthermore, there is no intention to be bound by any expressed or implied information presented in the preceding Summary section, or in the Detailed Description section. One or more embodiments are now described with reference to the drawings, wherein like reference numerals are utilized to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Various operations can be described as multiple discrete actions or operations in turn, in a manner that is most helpful in understanding the subject matter disclosed herein. However, the order of description should not be construed as to imply that these operations are necessarily order dependent. In particular, these operations can be performed in an order different from the order of presentation. Operations described can be performed in a different order from the described embodiment. Various additional operations can be performed, and/or described operations can be omitted in additional embodiments.

Turning now to the subject of material analysis and to the one or more embodiments described herein, one method of material analysis can employ an imaging device, such as an electron microscope (EM), such as a scanning electron microscope (SEM) or transmission electron microscope (TEM), and/or a focused ion beam (FIB) device. Generally, using electron microscopy, a sample can be targeted by an ion source, ultimately resulting in an emission of (and/or generation of) secondary charged particles, such as secondary electrons and/or secondary ions, that can be detected and registered to then generate an image of the sample.

Set up, writing of workflow code, testing of workflow code, and/or execution of experiments for this type of material analysis, among other imaging analysis procedures, can each be complex and manually intensive procedures. Furthermore, such procedures can employ expensive imaging devices, power, experiment bandwidth and user entity manual labor, while in many situations, a limited number of such imaging devices are available. Or, in one or more other situations, one or more such procedures can be outsourced, but better understanding of the one or more procedures in house can be desired. That is, put more generally, use of such NVS imaging devices can be costly (e.g., in terms of power, bandwidth, manual labor and/or the like) and even limited.

To account for one or more inabilities and/or deficiencies of existing frameworks for use of NVS imaging devices, including a mere limit on availability of such imaging devices to a user entity, one or more embodiments are described herein that can provide imaging device virtual simulation. Such simulation can be provided for any of the above-noted purposes, among others, of workflow testing, setup testing, experiment testing, training, learning and/or presentation of imaging device capabilities.

That is, the one or more embodiments described herein, using an automated simulation approach, can provide for generation of and use of a virtually simulated imaging device that can replicate and/or be similar to a non-virtually-simulated (NVS) imaging device. Briefly, this can allow for varied and high performance of the one or more above-noted procedures but separate from a NVS imaging device. In turn, availability of one or more existing NVS imaging devices can be increased, testing and learning can be improved (e.g., made more efficient and available) relative to the complex procedures for use of such NVS imaging devices, and/or a NVS imaging device can be replicated/simulated and/or presented to a prospective user before being commercially-available to market, among other uses.

More particularly, the one or more embodiments described herein can provide one or more imaging device simulation frameworks that can perform one or more processes comprising, but not limited to, generating a virtual environment comprising a simulated chamber of a simulated imaging device, generating a three-dimensional simulation of a simulated object within the simulated chamber, obtaining control signals from a set of controls for controlling the simulation framework and/or for controlling a NVS imaging device, generating a viewing of a modification of the simulated object with a simulated tool based on the obtaining, simulating a change to a parameter of the virtual environment based on a parameter setting of a NVS imaging device, outputting a notification of a failure of a simulated workflow within the virtual environment, and/or outputting a notification of a simulated touch interaction with a simulated object within the simulated chamber.

To achieve one or more of the above one or more processes, an imaging device virtual environment generating (IDVEG) system can access a datastore comprising one or more data records defining one or more virtual environment parameters, chamber definition data, sample definition data, tool definition data and/or the like. In connection therewith, the IDVEG system can determine one or more additional parameters, such as material, color, mass and/or dimension of any of the chamber, sample, tool and/or other element being and/or to be simulated, such as based on a change of a parameter of the virtual environment or based on obtaining a control signal.

In one or more embodiments, the automatic system can aid, such as suggest and/or control, one or more steps for facilitating capturing of one or more simulated images of the simulated chamber and one or more elements comprised therein (e.g., simulated sample, sample grid, tool, etc.). In one or more embodiments, the IDVEG system can output a suggestion to a change of a parameter setting for the virtual environment and/or for a workflow being simulated.

The automatic system can comprise one or more scientific instrument systems described herein, as well as one or more related methods, computing devices, and/or computer-readable media. For example, in one or more embodiments, a system can comprise a memory that can store computer executable components and a processor that executes the computer executable components stored in the memory. The computer executable components can comprise a rendering engine component that renders a virtual environment comprising a three-dimensional simulation of a simulated imaging device comprising a simulated chamber having a simulated object for analysis being rendered therein, and a simulating component that generates simulation data corresponding to a directed interaction comprising a three-dimensional modification of the simulated object.

As indicated above, the one or more embodiments disclosed herein can achieve improved performance relative to existing approaches. Indeed, existing approaches may comprise at most use of a NVS imaging device for training, testing, learning and/or the like, without any use of a simulated imaging device and/or chamber provided for viewing and use via a virtual environment. Even in a case of simulation thereof, a two-dimensional approach is at most provided, failing to allow for testing of process flows, material placements, touch interactions and/or the like.

Differently, various one or more of the embodiments disclosed herein can improve upon existing approaches to achieve the technical advantages of accurate, repeatable and/or configurable virtual testing of imaging device process flows, material placements and/or touch interactions. Furthermore, the one or more embodiments disclosed herein can improve upon existing approaches to achieve additional technical advantages of increased availability to the controls of an imaging device and/or to use of an imaging device of some type (whether virtual as provided by the one or more embodiments discussed herein or a NVS imaging device due to other use of a virtual twin by another user entity). Accordingly, the one or more embodiments described herein can allow for more efficient, more accurate, more realistic, and/or less costly virtual processes (e.g., less costly in terms of NVS imaging device use, power, bandwidth, etc.).

That is, the one or more embodiments disclosed herein provide improvements to scientific instrument technology (e.g., improvements in the computer technology supporting such scientific instruments, among other improvements), which can be employed in various fields including microscopic imaging, optics, signal processing, spectroscopy, and nuclear magnetic resonance (NMR), without being limited thereto.

The above-mentioned technical advantages are not achievable by routine and existing approaches, and all user entities of systems including such embodiments can benefit from these advantages (e.g., by assisting the user entity in the performance of a technical task, such as allowing for operation of an imaging device, but instead in a virtual environment, instead of based on a physical chamber).

The technical features of the embodiments disclosed herein are thus decidedly unconventional in the field of microscopic imaging, in addition to the fields of optics, signal processing, spectroscopy, and/or NMR, without being limited thereto, as are combinations of the features of the embodiments disclosed herein.

As discussed further herein, various aspects of the embodiments disclosed herein can improve the functionality of a computer itself. That is, the computational and user interface features disclosed herein do not involve only the collection and comparison of information but instead apply new analytical and technical techniques to change the operation of the computer-analysis of material compounds. For example, based on the application of the various virtual parameters, such as for lighting, contrast and/or simulated imaging voltages, a more efficient use of an imaging device virtual environment can be obtained. These processes can all be performed automatically based on analysis of the produced virtual image by the one or more embodiments, different from existing frameworks that are unable to provide simulated imaging device images. Accordingly, a corresponding computer-directed process of imaging device virtual simulation itself can be made easier and more efficient through self-parameterizing. As such, a non-limiting system described herein, comprising an imaging device virtual environment generating (IDVEG) system 502/602, can be self-improving.

The present disclosure thus introduces functionality that neither an existing computing device, nor a human, could perform. Rather, such existing computing devices would instead require use of a physical and/or non-virtually-simulated (NVS) imaging device. In view of the time, energy, human error and/or lack of automation involved, in addition to the lack of accurate sample support identification, it is not practical to operate within the confines of existing approaches for all tasks related to imaging devices generally.

In one or more cases, the one or more embodiments discussed herein can provide for scaled rendering and/or use of an imaging device virtual environment (e.g., simulation of an imaging device chamber). For example, one or more imaging device virtual environment generating (IDVEG) systems can be coupled to one or more imaging device servers. Additionally, and/or alternatively, one or more imaging device virtual environment generating (IDVEG) systems can be coupled to one another and/or operate separately from one another. In any of such cases, a plurality of simulated chambers and/or other virtual imaging device environments can be generated and interacted with.

In view of the above, and the additional description provided below, the embodiments of the present disclosure can serve any of a number of technical purposes, such as controlling a specific technical system or process; determining from measurements how to control a machine; digital audio, image, or video enhancement or analysis; separation of material sources in a mixed signal; generating data for reliable and/or efficient transmission or storage; providing estimates and confidence intervals for material samples; or providing a faster processing of sensor data. In particular, the present disclosure provides technical solutions to technical problems, including, but not limited to, accurate and repeatable imaging device virtual environment generation, accurate and repeatable imaging device chamber simulation, and/or accurate and repeatable generation of interactions with such generations/simulations that provide for feedback to an imaging device server in place of feedback from a NVS imaging device.

The embodiments disclosed herein thus can provide one or more improvements to material analysis technology (e.g., improvements in the computer technology supporting material analysis, among other improvements).

As used herein, the phrase “based on” should be understood to mean “based at least in part on,” unless otherwise specified.

As used herein, the term “component” can refer to an atomic element, molecular element, phase of an atomic or molecular element, or combination thereof.

As used herein, the terms “compound” and “precursor” can be used interchangeably.

As used herein, the term “data” can comprise metadata.

As used herein, the terms “entity,” “requesting entity,” and “user entity” can refer to a machine, device, component, hardware, software, smart device, party, organization, individual and/or human.

One or more embodiments are now described with reference to the drawings, where like referenced numerals are used to refer to like drawing elements throughout. In the following description, for purposes of explanation, numerous specific details are set forth in order to provide a more thorough understanding of the one or more embodiments. It is evident in various cases, however, that the one or more embodiments can be practiced without these specific details.

Further, it should be appreciated that the embodiments depicted in one or more figures described herein are for illustration only, and as such, the architecture of embodiments is not limited to the systems, devices and/or components depicted therein, nor to any particular order, connection and/or coupling of systems, devices and/or components depicted therein.

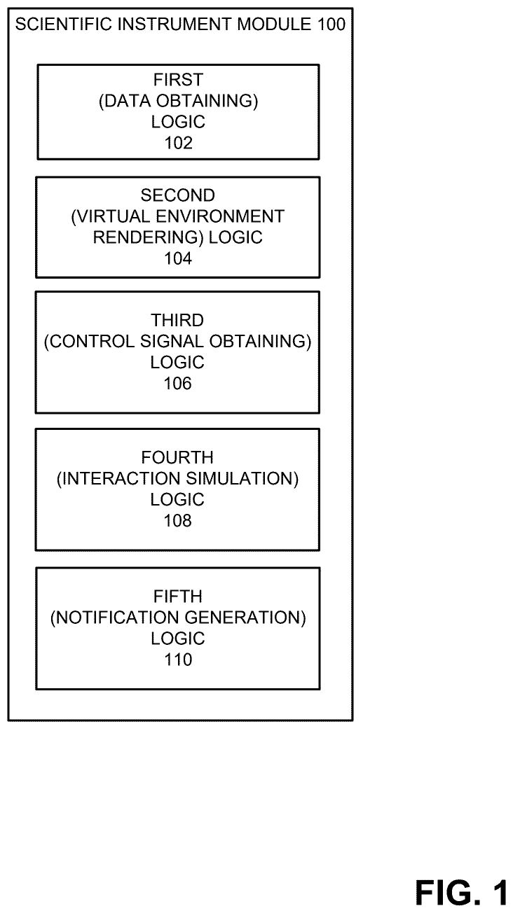

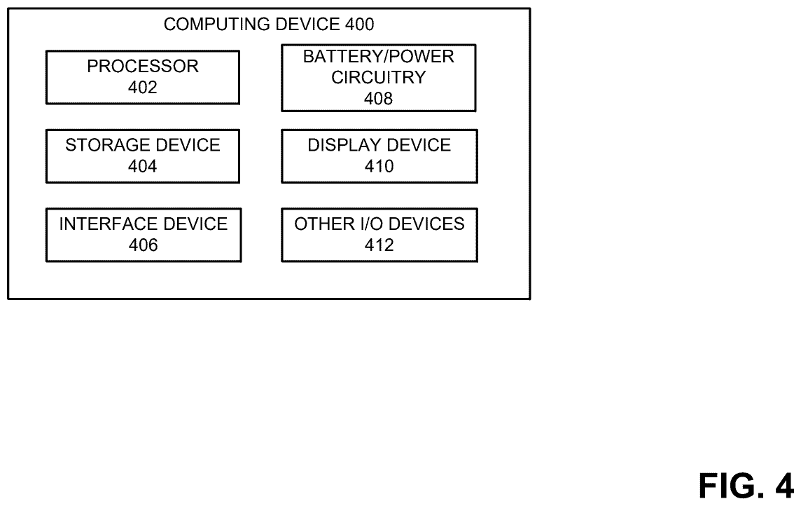

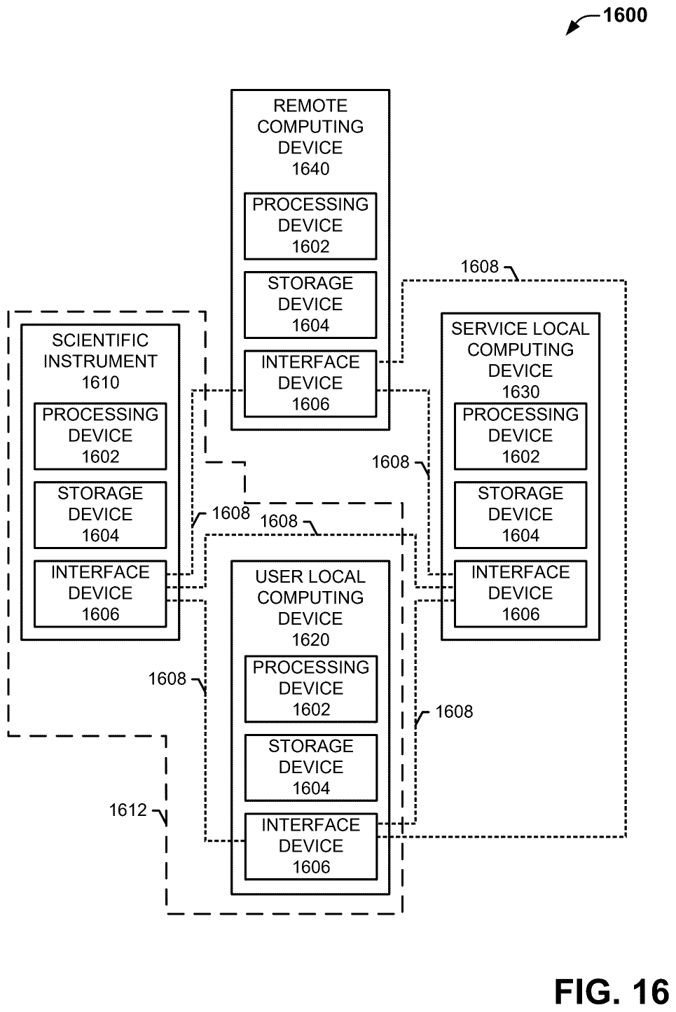

Turning now in particular to the one or more figures, and first to FIG. 1, illustrated is a block diagram of a scientific instrument module 100 for preparation and setup related to performing material analysis operations using a microscopic imaging technique, in accordance with various embodiments described herein. The scientific instrument module 100 can be implemented by circuitry (e.g., including electrical and/or optical components), such as a programmed computing device. The logic of the scientific instrument module 100 can be included in a single computing device or can be distributed across multiple computing devices that are in communication with each other as appropriate. Examples of computing devices that can, singly or in combination, implement the scientific instrument module 100 are discussed herein with reference to the computing device 400 of FIG. 4, and examples of systems of interconnected computing devices, in which the scientific instrument module 100 can be implemented across one or more of the computing devices, is discussed herein with reference to the scientific instrument system 1600 of FIG. 16.

The scientific instrument module 100 can function in correspondence with an imaging system 630 comprising an imaging device 631. The scientific instrument module 100 can include first logic 102, second logic 104, third logic 106, fourth logic 108 and fifth logic 110. As used herein, the term “logic” can include an apparatus that is to perform a set of operations associated with the logic. For example, any of the logic elements included in the module 100 can be implemented by one or more computing devices programmed with instructions to cause one or more processing devices of the computing devices to perform the associated set of operations. In one or more particular embodiments, a logic element can include one or more non-transitory computer-readable media having instructions thereon that, when executed by one or more processing devices of one or more computing devices, can cause the one or more computing devices to perform the associated set of operations.

As used herein, the term “module” can refer to a collection of one or more logic elements that, together, perform a function associated with the module. Different ones of the logic elements in a module can take the same form or can take different forms. For example, some logic in a module can be implemented by a programmed general-purpose processing device, while other logic in a module can be implemented by an application-specific integrated circuit (ASIC). In another example, different ones of the logic elements in a module can be associated with different sets of instructions executed by one or more processing devices. A module can omit one or more of the logic elements depicted in the associated drawing; for example, a module can include a subset of the logic elements depicted in the associated drawing when that module is to perform a subset of the operations discussed herein with reference to that module.

The first logic 102 can obtain, cause obtaining of and/or direct obtaining of information (e.g., data, metadata) that can be employed for bounding, limiting and/or rendering a virtual environment. That is, the first logic 102 can search for, identify, request, receive and/or otherwise obtain such information related to the virtual environment to be prepared, including, but not limited to, information related to a NVS imaging device, chamber, sample, sample support and/or sample modification/movement tool.

The second logic 104 can render, cause rendering of and/or direct rendering of a virtual environment designed to imitate, replicate and/or otherwise serve as an imaging device chamber, which can comprise a sample platform, sample support, sample and/or sample modification tool. That is, the second logic 104 can provide the rendering based on an output by and/or relative to the first logic 102. In one or more embodiments, the second logic 104 can be comprised by and/or direct a rendering engine.

The third logic 106 can obtain, cause obtaining of and/or direct obtaining of a control signal for analysis to generate a modification within the virtual environment. The third logic 106 can search for, identify, request, receive and/or otherwise obtain such control signal. The control signal can be related to changing a parameter of the virtual environment, movement of the virtual environment, interaction with an element (e.g., sample support, sample and/or sample modification tool) of the virtual environment. The control signal can be obtained from a set of controls or from an imaging device automation application, such as is existingly employed to control a NVS imaging device.

The fourth logic 108 can modify, cause modification of and/or direct modification of the virtual environment output by and/or relative to the second logic 104 based on output by and/or relative to the third logic 106. The modifying can comprise generating an interaction with any one or more elements of the virtual environment, changing a parameter of the virtual environment, moving any one or more elements of the virtual environment, and/or an interaction otherwise of and/or with the generated virtual environment.

The fifth logic 110 can generate, cause generation of and/or direct generation of a notification based on an output of and/or respective to the fourth logic 108. That is, the notification can comprise a notification of a process flow failure or element touch interaction related to any of the first logic 102 through fourth logic 108.

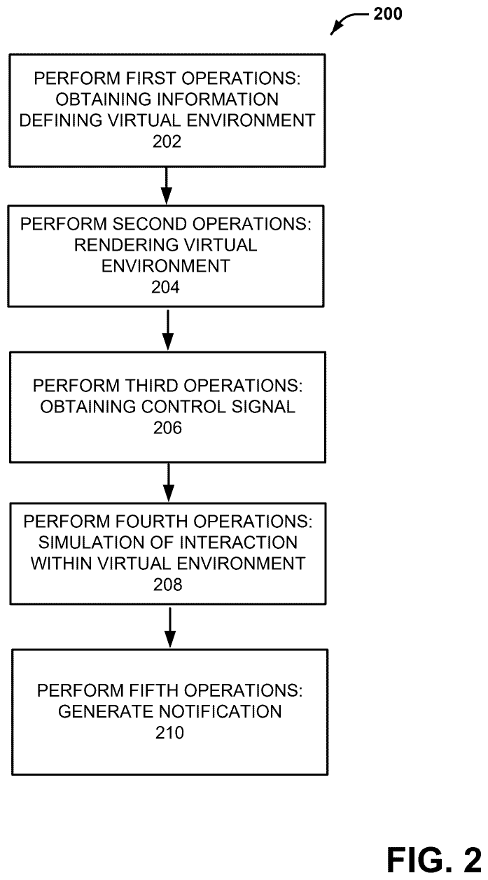

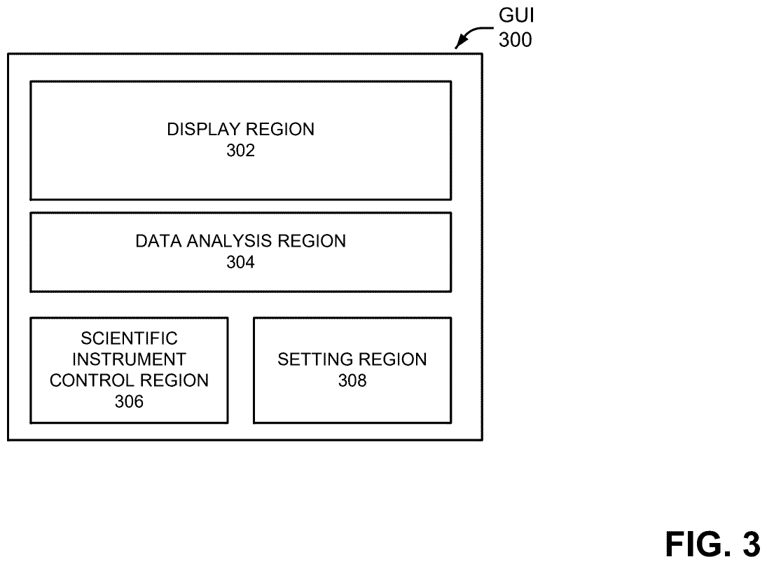

FIG. 2 illustrates a flow diagram of a method 200 of performing operations, by the scientific instrument module 100, in accordance with various embodiments. Although the operations of the method 200 can be illustrated with reference to particular embodiments disclosed herein (e.g., the scientific instrument module 100 discussed herein with reference to FIG. 1, the GUI 300 discussed herein with reference to FIG. 3, the computing device 400 discussed herein with reference to FIG. 4, and/or the scientific instrument system 1600 discussed herein with reference to FIG. 16), the method 200 can be used in any suitable setting to perform any suitable operations. Operations are illustrated once each and in a particular order in FIG. 2, but the operations can be reordered and/or repeated as desired and appropriate (e.g., different operations performed can be performed in parallel, as suitable).

At 202, first operations can be performed. For example, the first logic 102 of the module 100 can perform the first operations 202. The first operations 202 can comprise obtaining, causing obtaining of and/or directing obtaining of information (e.g., data, metadata) that can be employed for defining and generating a virtual environment. In one or more embodiments, the information can be related to any one or more aspects of the virtual environment to be prepared, including, but not limited to, information related to a NVS imaging device, chamber, sample, sample support and/or sample modification tool.

At 204, second operations can be performed. For example, the second logic 104 of the module 100 can perform the second operations 204. The second operations 204 can comprise rendering, directing rendering of and/or causing rendering of a virtual environment configured, such as being designed and/or configured, to imitate, replicate and/or otherwise serve as an imaging device chamber. In one or more embodiments, the simulated chamber can comprise a sample platform, sample support, sample (e.g., tissue sample) and/or sample modification tool.

At 206, third operations can be performed. For example, the third logic 106 of the module 100 can perform the third operations 206. The third operations 206 can comprise obtaining, causing obtaining of and/or directing obtaining of a control signal that can be employed for the fourth operations 208. For example, the control signal can be related to changing a parameter of the virtual environment, movement of the virtual environment, interaction with an element (e.g., sample support, sample and/or sample modification tool) of the virtual environment. The control signal can be obtained from a set of controls or from an imaging device automation application, such as is existingly employed to control a NVS imaging device.

At 208, fourth operations can be performed. For example, the fourth logic 108 of the module 100 can perform the fourth operations 208. The fourth operations 208 can comprise simulating, directing simulation of and/or causing simulation of an interaction with/to any one or more elements of the virtual environment. A modifying comprised by the interaction can comprise changing a parameter of the virtual environment, moving any one or more elements of the virtual environment, and/or an interaction otherwise of and/or with the generated virtual environment.

At 210, fifth operations can be performed. For example, the fifth logic 110 of the module 100 can perform the fifth operations 210. The fifth operations 210 can comprise generating, directing generation of and/or causing generation of a notification. The notification can comprise a notification of a process flow failure or element touch interaction, such as related to the performance of the fourth operations 208.

The scientific instrument methods disclosed herein can include interactions with a user entity (e.g., via the user local computing device 1620 discussed herein with reference to FIG. 16). These interactions can include providing information to and/or receiving information from the user entity (e.g., information regarding the operation of a scientific instrument such as the scientific instrument 1610 of FIG. 16, information regarding a sample being analyzed or other test or measurement performed by a scientific instrument, information retrieved from a local or remote database, or other information) or providing an option for a user entity to input commands (e.g., to control the operation of a scientific instrument such as the scientific instrument 1610 of FIG. 16, or to control the analysis of data generated by a scientific instrument), queries (e.g., to a local or remote database), or other information. In some embodiments, these interactions can be performed through a graphical user interface (GUI) that includes a visual display on a display device (e.g., the display device 410 discussed herein with reference to FIG. 4) that provides outputs to the user entity and/or prompts the user entity to provide inputs (e.g., via one or more input devices, such as a keyboard, mouse, trackpad, or touchscreen, included in the other I/O devices 412 discussed herein with reference to FIG. 4). The scientific instrument system 1600 disclosed herein can include any suitable GUIs for interaction with a user entity.

Turning next to FIG. 3, depicted is an example GUI 300 that can be used in the performance of some or all of the methods described herein, in accordance with various embodiments described herein. As noted above, the GUI 300 can be provided on a display device (e.g., the display device 410 discussed herein with reference to FIG. 4) of a computing device (e.g., the computing device 400 discussed herein with reference to FIG. 4) of a scientific instrument system (e.g., the scientific instrument system 1600 discussed herein with reference to FIG. 16), and a user entity can interact with the GUI 300 using any suitable input device (e.g., any of the input devices included in the other I/O devices 412 discussed herein with reference to FIG. 4) and input technique (e.g., movement of a cursor, motion capture, facial recognition, gesture detection, voice recognition, actuation of buttons, etc.).

The GUI 300 can include a data display region 302, a data analysis region 304, a scientific instrument control region 306, and a settings region 308. The particular number and arrangement of regions depicted in FIG. 3 is merely illustrative, and any number and arrangement of regions, including any desired features thereof, can be included in a GUI 300.

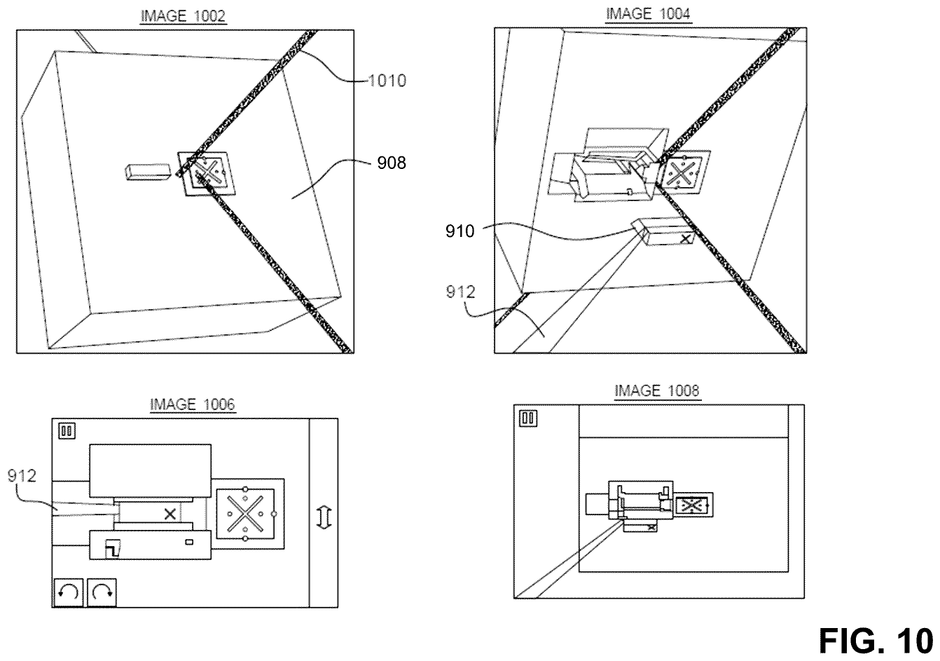

The data display region 302 can display data generated by a scientific instrument (e.g., the scientific instrument 1610 discussed herein with reference to FIG. 16). For example, the data display region 302 can display one or more output images of any of FIGS. 10-12, described blow, including one or more simulated images, virtual environment images, text, graphs, charts and/or matrices without being limited thereto.

The data analysis region 304 can display the results of data analysis (e.g., the results of analyzing the data illustrated in the data display region 302 and/or other data). For example, the data analysis region 304 can display one or more notifications 660 and/or suggestions 670. In one or more embodiments, the data display region 302 and the data analysis region 304 can be combined in the GUI 300 (e.g., to include data output from a scientific instrument, and some analysis of the data, in a common graph or region).

The scientific instrument control region 306 can include options that can allow the user entity to control a scientific instrument (e.g., the scientific instrument 1610 discussed herein with reference to FIG. 16). For example, the scientific instrument control region 306 can include one or more controls for inputting one or more metrics of interest.

The settings region 308 can include options that allow the user entity to control the features and functions of the GUI 300 (and/or other GUIs) and/or perform common computing operations with respect to the data display region 302 and data analysis region 304 (e.g., saving data on a storage device, such as the storage device 404 discussed herein with reference to FIG. 4, sending data to another user entity, labeling data, etc.). For example, the settings region 308 can include one or more options to alter color, fill or format of illustrations, such as an illustration related to one or more images and/or schematics of FIGS. 10-12.

As noted above, the scientific instrument module 100 can be implemented by one or more computing devices. Accordingly, discussion next turns to FIG. 4, which illustrates a block diagram of a computing device 400 that can perform some or all of the scientific instrument methods disclosed herein, in accordance with various embodiments. In one or more embodiments, the scientific instrument module 100 can be implemented by a single computing device 400 or by multiple computing devices 400. Further, as discussed below, a computing device 400 (or multiple computing devices 400) that implements the scientific instrument module 100 can be part of one or more of the scientific instruments 1610, the user local computing device 1620, the service local computing device 1630, or the remote computing device 1640 of FIG. 16.

The computing device 400 of FIG. 4 is illustrated as having a number of components, but any one or more of these components can be omitted or duplicated, as suitable for the application and setting. As illustrated, these components can include one or more of a processor 402, storage device 404, interface device 406, battery/power circuitry 408, display device 410 and other input/output (I/O) devices 412, as will be described below.

In one or more embodiments, one or more of the components included in the computing device 400 can be attached to one or more motherboards and enclosed in a housing (e.g., including plastic, metal, and/or other materials). In one or more embodiments, some these components can be fabricated onto a single system-on-a-chip (SoC) (e.g., an SoC can include one or more processors 402 and one or more storage devices 404). Additionally, in one or more embodiments, the computing device 400 can omit one or more of the components illustrated in FIG. 4. In one or more embodiments, the computing device 400 can include interface circuitry (not shown) for coupling to the one or more components using any suitable interface (e.g., a Universal Serial Bus (USB) interface, a High-Definition Multimedia Interface (HDMI) interface, a Controller Area Network (CAN) interface, a Serial Peripheral Interface (SPI) interface, an Ethernet interface, a wireless interface, or any other appropriate interface). For example, the computing device 400 can omit a display device 410, but can include display device interface circuitry (e.g., a connector and driver circuitry) to which a display device 410 can be coupled.

The computing device 400 can include the processor 402 (e.g., one or more processing devices). As used herein, the term “processing device” can refer to any device or portion of a device that processes electronic data from registers and/or memory to transform that electronic data into other electronic data that can be stored in registers and/or memory. The processor 402 can include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The computing device 400 can include a storage device 404 (e.g., one or more storage devices). The storage device 404 can include one or more memory devices such as random-access memory (RAM) (e.g., static RAM (SRAM) devices, magnetic RAM (MRAM) devices, dynamic RAM (DRAM) devices, resistive RAM (RRAM) devices, or conductive-bridging RAM (CBRAM) devices), hard drive-based memory devices, solid-state memory devices, networked drives, cloud drives, or any combination of memory devices. In one or more embodiments, the storage device 404 can include memory that shares a die with a processor 402. In such an embodiment, the memory can be used as cache memory and can include embedded dynamic random-access memory (eDRAM) or spin transfer torque magnetic random-access memory (STT-MRAM), for example. In one or more embodiments, the storage device 404 can include non-transitory computer readable media having instructions thereon that, when executed by one or more processing devices (e.g., the processor 402), cause the computing device 400 to perform any appropriate ones of or portions of the methods disclosed herein.

The computing device 400 can comprise an interface device 406 (e.g., one or more interface devices 406). The interface device 406 can include one or more communication chips, connectors, and/or other hardware and software to govern communications between the computing device 400 and other computing devices. For example, the interface device 406 can include circuitry for managing wireless communications for the transfer of data to and from the computing device 400. The term “wireless” and its derivatives can be used to describe circuits, devices, systems, methods, techniques, communications channels, etc., that can communicate data through the use of modulated electromagnetic radiation through a nonsolid medium. The term does not imply that the associated devices do not contain any wires, although in one or more embodiments the associated devices might not contain any wires. Circuitry included in the interface device 406 for managing wireless communications can implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). In one or more embodiments, circuitry included in the interface device 406 for managing wireless communications can operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. In one or more embodiments, circuitry included in the interface device 406 for managing wireless communications can operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). In one or more embodiments, circuitry included in the interface device 406 for managing wireless communications can operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. In one or more embodiments, the interface device 406 can include one or more antennas (e.g., one or more antenna arrays) to receipt and/or transmission of wireless communications.

In one or more embodiments, the interface device 406 can include circuitry for managing wired communications, such as electrical, optical, or any other suitable communication protocols. For example, the interface device 406 can include circuitry to support communications in accordance with Ethernet technologies. In one or more embodiments, the interface device 406 can support both wireless and wired communication, and/or can support multiple wired communication protocols and/or multiple wireless communication protocols. For example, a first set of circuitry of the interface device 406 can be dedicated to shorter-range wireless communications such as Wi-Fi or Bluetooth, and a second set of circuitry of the interface device 406 can be dedicated to longer-range wireless communications such as global positioning system (GPS), EDGE, GPRS, CDMA, WiMAX, LTE, EV-DO, or others. In one or more embodiments, a first set of circuitry of the interface device 406 can be dedicated to wireless communications, and a second set of circuitry of the interface device 406 can be dedicated to wired communications.

The computing device 400 can include battery/power circuitry 408. The battery/power circuitry 408 can include one or more energy storage devices (e.g., batteries or capacitors) and/or circuitry for coupling components of the computing device 400 to an energy source separate from the computing device 400 (e.g., alternating current line power).

The computing device 400 can include a display device 410 (e.g., multiple display devices). The display device 410 can include any visual indicators, such as a heads-up display, a computer monitor, a projector, a touchscreen display, a liquid crystal display (LCD), a light-emitting diode display, or a flat panel display.

The computing device 400 can include other input/output (I/O) devices 412. The other I/O devices 412 can include one or more audio output devices (e.g., speakers, headsets, earbuds, alarms, etc.), one or more audio input devices (e.g., microphones or microphone arrays), location devices (e.g., GPS devices in communication with a satellite-based system to receive a location of the computing device 400, as known in the art), audio codecs, video codecs, printers, sensors (e.g., thermocouples or other temperature sensors, humidity sensors, pressure sensors, vibration sensors, accelerometers, gyroscopes, etc.), image capture devices such as cameras, keyboards, cursor control devices such as a mouse, a stylus, a trackball, or a touchpad, bar code readers, Quick Response (QR) code readers, or radio frequency identification (RFID) readers, for example.

The computing device 400 can have any suitable form factor for its application and setting, such as a handheld or mobile computing device (e.g., a cell phone, a smart phone, a mobile internet device, a tablet computer, a laptop computer, a netbook computer, an ultrabook computer, a personal digital assistant (PDA), an ultra mobile personal computer, etc.), a desktop computing device, or a server computing device or other networked computing component.

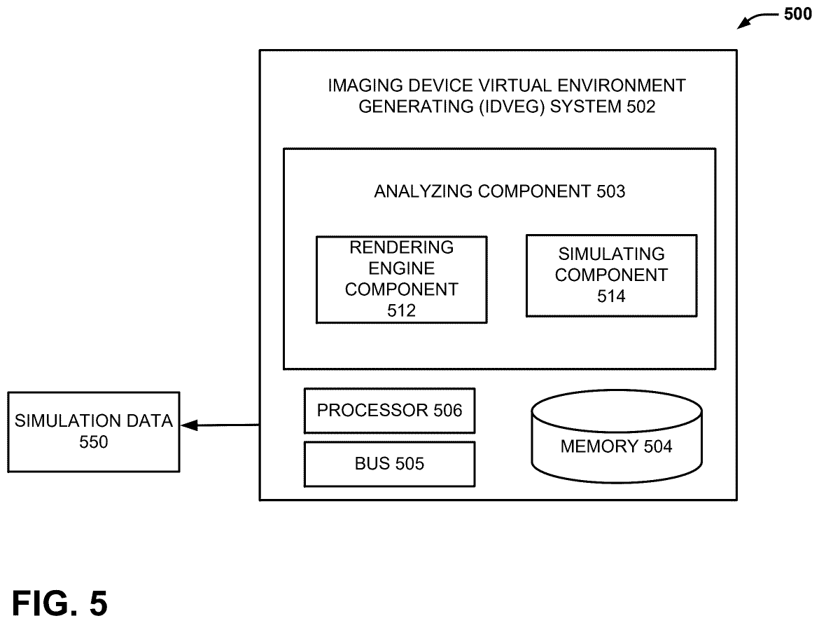

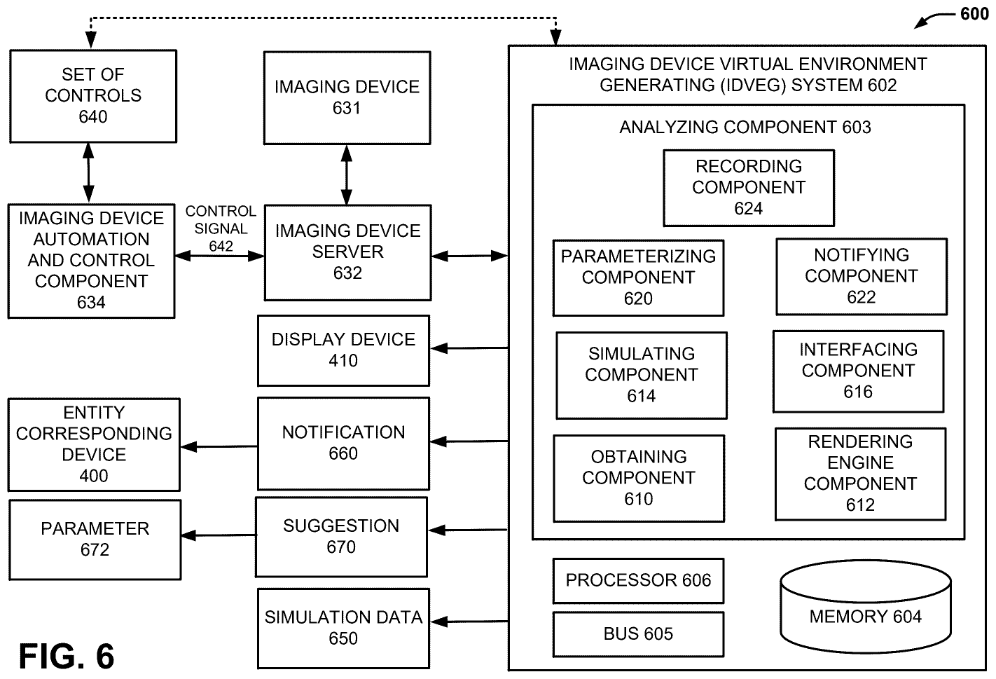

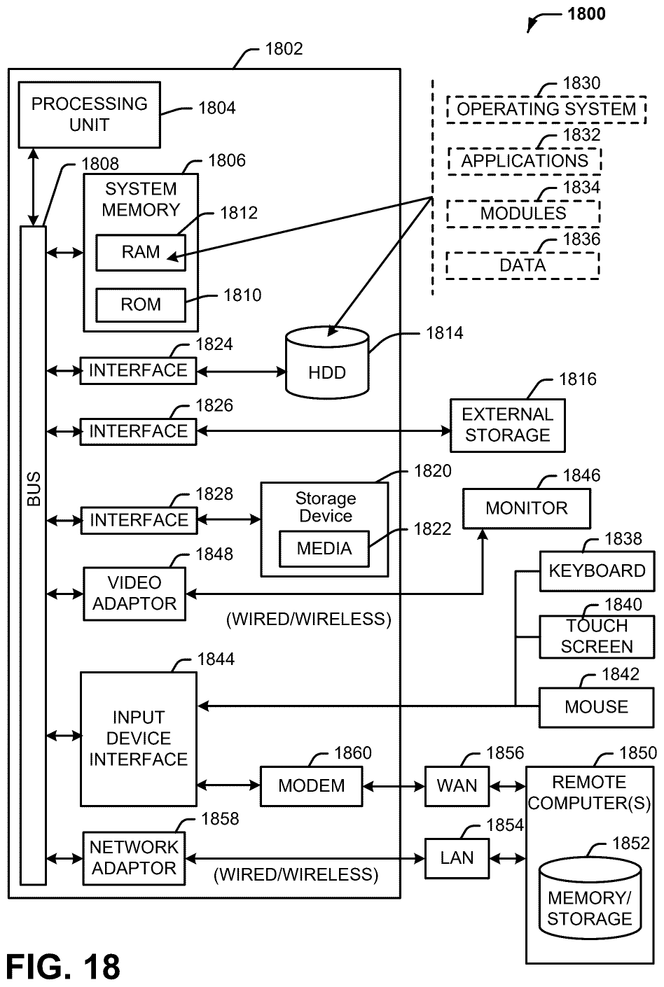

Referring next to FIGS. 5 and 6, in one or more embodiments, the non-limiting systems 500 and/or 600 illustrated at FIGS. 5 and 6, and/or systems thereof, can further comprise one or more computer and/or computing-based elements described herein with reference to a computing environment, such as the computing environment 1800 illustrated at FIG. 18. In one or more described embodiments, computer and/or computing-based elements can be used in connection with implementing one or more of the systems, devices, components and/or computer-implemented operations shown and/or described in connection with FIGS. 5 and/or 6 and/or with other figures described herein.

Turning first to FIG. 5, the figure illustrates a block diagram of an example, non-limiting system 500 that can comprise an imaging device virtual environment generation (IDVEG) system 502. The IDVEG system 502 can facilitate virtual simulation of an imaging device (e.g., a real-world device or a non-existent imaging device that does not exist in the real world).

In one or more embodiments, the IDVEG system 502 can be at least partially comprised by the computing device 400.

It is noted that the IDVEG system 502 is only briefly detailed to provide but a lead-in to a more complex and/or more expansive IDVEG system 602 as illustrated at FIG. 6. That is, further detail regarding processes that can be performed by one or more embodiments described herein will be provided below relative to the non-limiting system 600 of FIG. 6.

Still referring to FIG. 5, the IDVEG system 502 can comprise at least a memory 504, bus 505, processor 506, rendering engine component 512 and simulating component 514. The processor 506 can be the same as the processor 402, comprised by the processor 402 or different therefrom. The memory 504 can be the same as the storage device 404, comprised by the storage device 404 or different therefrom.

Using the above-noted components, the IDVEG system 502 can facilitate a process to first virtually render a virtual environment comprising a simulated imaging device chamber, and second, provide for three-dimensional (3D) simulated interaction within the chamber to allow for making conclusions that can apply to a real-world or NVS imaging device.

Generally, the simulated imaging device can be a digital twin (e.g., a copy or at least a partial copy) of an existing or available NVS imaging device, can be similar to a NVS imaging device, can be similar to a not-yet-commercially-available NVS imaging device, and/or can be unrelated to (e.g., not similar to) any NVS imaging device, without being limited thereto. Accordingly, various options and various purposes for use of the simulated imaging device can correspond thereto, as will be explained below in detail.

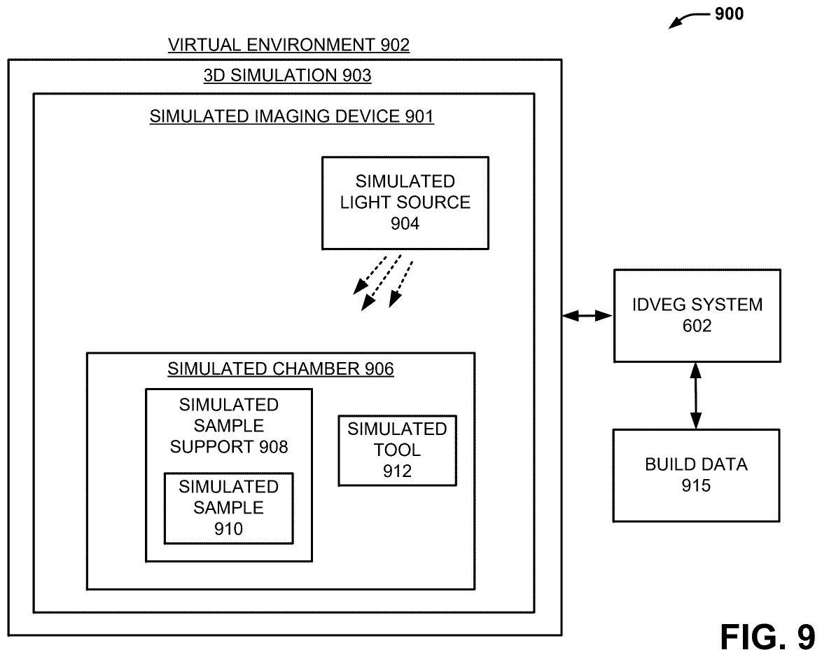

Generally, turning briefly in addition to the block diagram 900 of FIG. 9, the rendering engine component 512 can render a virtual environment (e.g., virtual environment 902) comprising a three-dimensional simulation (e.g., 3D simulation 903) of a simulated imaging device (e.g., simulated imaging device 901) comprising a simulated chamber (e.g., simulated chamber 906, such as an inner chamber) having a simulated object (e.g., a simulated sample support 908, simulated sample 910 and/or simulated tool 912) for analysis being rendered therein.

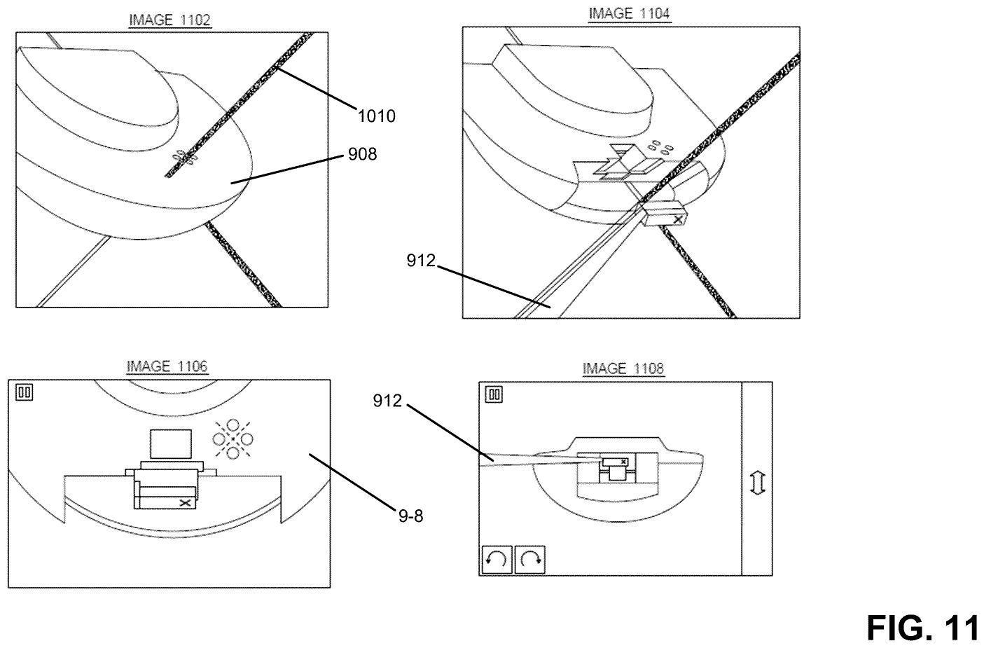

The simulating component 514 can, employing the rendering, generate simulation data 550 corresponding to a directed interaction (e.g., as illustrated at FIGS. 10 and 11) comprising a three-dimensional modification (e.g., as illustrated at FIGS. 10 and 11) of the simulated object. For example, a simulated tool 912 or other simulated element can interact with the simulated object to simulate a real-world interaction, whether related to a coded control process or related to an ad hoc interaction, for example.

The simulation data 550, as will be explained below in detail, can be output from the IDVEG system 602 and/or otherwise made available from the IDVEG system 602 for use in generating a display, such as at the display device 410, and/or as a portion of back-and-forth communication between the IDVEG system 602 and an AAC component existingly controlling an NVS imaging device. The simulation data 550 can comprise data and/or metadata in any suitable format.

The rendering engine component 512 and simulating component 514 can be operatively coupled to the processor 506 which can be operatively coupled to the memory 504. The bus 505 can provide for the operative coupling. The processor 506 can rendering engine component 512 and simulating component 514 engine component 512 and the interfacing component 518. The rendering engine component 512 and simulating component 514 can be stored at the memory 504.

In general, the non-limiting system 500 can employ any suitable method of communication (e.g., electronic, communicative, internet, infrared, fiber, etc.) to provide communication between the IDVEG system 502, an imaging system employed at least partially employed by the IDVEG system 502, and/or any device associated with a user entity.

Turning next to FIG. 6, a non-limiting system 600 is illustrated that can comprise a IDVEG system 602 and an imaging system 630. Repetitive description of like elements and/or processes employed in respective embodiments is omitted for sake of brevity. Description relative to an embodiment of FIG. 5 can be applicable to an embodiment of FIG. 6. Likewise, description relative to an embodiment of FIG. 6 can be applicable to an embodiment of FIG. 5.

Generally, the IDVEG system 602 can facilitate a process for virtual 3D simulation of a simulated imaging device 901. This process can be facilitated by rendering of, interaction with and/or control of a simulated sample 910 within a simulated chamber 906 of the simulated imaging device 901.

In one or more embodiments, the IDVEG system 602 can be at least partially comprised by the computing device 400.

In one or more embodiments, the IDVEG system 602 can at least partially comprise the imaging system 630.

One or more communications between one or more components of the non-limiting system 600 can be provided by wired and/or wireless means including, but not limited to, employing a cellular network, a wide area network (WAN) (e.g., the Internet), and/or a local area network (LAN). Suitable wired or wireless technologies for supporting the communications can include, without being limited to, wireless fidelity (Wi-Fi), global system for mobile communications (GSM), universal mobile telecommunications system (UMTS), worldwide interoperability for microwave access (WiMAX), enhanced general packet radio service (enhanced GPRS), third generation partnership project (3GPP) long term evolution (LTE), third generation partnership project 2 (3GPP2) ultra-mobile broadband (UMB), high speed packet access (HSPA), Zigbee and other 802.XX wireless technologies and/or legacy telecommunication technologies, BLUETOOTH®, Session Initiation Protocol (SIP), ZIGBEE®, RF4CE protocol, WirelessHART protocol, 6LoWPAN (Ipv6 over Low power Wireless Area Networks), Z-Wave, an advanced and/or adaptive network technology (ANT), an ultra-wideband (UWB) standard protocol and/or other proprietary and/or non-proprietary communication protocols.

The IDVEG system 602 can be associated with, such as accessible via, a cloud computing environment, such as the cloud computing environment 1800 of FIG. 18.

The IDVEG system 602 can comprise a plurality of components. The components can comprise a memory 604, processor 606, bus 605, obtaining component 610, rendering engine component 612, simulating component 614, interfacing component 616, parameterizing component 620, notifying component 622 and/or recording component 624. Using these components, the IDVEG system 602 can render, modify and control a virtual simulation of an imaging device. In this way, an IDVEG system 602 can be employed in correspondence with an imaging device automation and control (AAC) component 634 to provide for real-world-based control and feedback in conjunction with the virtual simulation, separate from use of a real-world or NVS imaging device, as will be discussed below in detail.

Discussion next turns to the processor 606, memory 604 and bus 605 of the IDVEG system 602. For example, in one or more embodiments, the IDVEG system 602 can comprise the processor 606 (e.g., computer processing unit, microprocessor, classical processor, quantum processor and/or like processor). In one or more embodiments, a component associated with IDVEG system 602, as described herein with or without reference to the one or more figures of the one or more embodiments, can comprise one or more computer and/or machine readable, writable and/or executable components and/or instructions that can be executed by processor 606 to provide performance of one or more processes defined by such component and/or instruction. In one or more embodiments, the processor 606 can comprise the obtaining component 610, rendering engine component 612, simulating component 614, interfacing component 616, parameterizing component 620, notifying component 622 and/or recording component 624.

In one or more embodiments, the IDVEG system 602 can comprise the computer-readable memory 604 that can be operably connected to the processor 606. The memory 604 can store computer-executable instructions that, upon execution by the processor 606, can cause the processor 606 and/or one or more other components of the IDVEG system 602 (e.g., obtaining component 610, rendering engine component 612, simulating component 614, interfacing component 616, parameterizing component 620, notifying component 622 and/or recording component 624) to perform one or more actions. In one or more embodiments, the memory 604 can store computer-executable components (e.g., obtaining component 610, rendering engine component 612, simulating component 614, interfacing component 616, parameterizing component 620, notifying component 622 and/or recording component 624).

The IDVEG system 602 and/or a component thereof as described herein, can be communicatively, electrically, operatively, optically and/or otherwise coupled to one another via a bus 605. Bus 605 can comprise one or more of a memory bus, memory controller, peripheral bus, external bus, local bus, quantum bus and/or another type of bus that can employ one or more bus architectures. One or more of these examples of bus 605 can be employed.

In one or more embodiments, the IDVEG system 602 can be coupled (e.g., communicatively, electrically, operatively, optically and/or like function) to one or more external systems (e.g., a non-illustrated electrical output production system, one or more output targets and/or an output target controller), sources and/or devices (e.g., classical and/or quantum computing devices, communication devices and/or like devices), such as via a network. In one or more embodiments, one or more of the components of the IDVEG system 602 and/or of the non-limiting system 600 can reside in the cloud, and/or can reside locally in a local computing environment (e.g., at a specified location).

In addition to the processor 606 and/or memory 604 described above, the IDVEG system 602 can comprise one or more computer and/or machine readable, writable and/or executable components and/or instructions that, when executed by processor 606, can provide performance of one or more operations defined by such component and/or instruction.

Discussion next turns to one or more additional components of the IDVEG system 602.

However, first, it is noted that in one or more embodiments, the obtaining component 610, rendering engine component 612, simulating component 614, interfacing component 616, parameterizing component 620, notifying component 622 and/or recording component 624 can be implemented independently, without one or more other of the obtaining component 610, rendering engine component 612, simulating component 614, interfacing component 616, parameterizing component 620, notifying component 622 and/or recording component 624. Additionally and/or alternatively, the obtaining component 610, rendering engine component 612, simulating component 614, interfacing component 616, parameterizing component 620, notifying component 622 and/or recording component 624 can be comprised by a high-level analyzing component 603, one or more of the below-described functions of the obtaining component 610, rendering engine component 612, simulating component 614, interfacing component 616, parameterizing component 620, notifying component 622 and/or recording component 624 can be performed by the high-level analyzing component 603, and/or the obtaining component 610, rendering engine component 612, simulating component 614, interfacing component 616, parameterizing component 620, notifying component 622 and/or recording component 624 can be omitted with the high-level analyzing component 603 performing one or more of the below-described functions of the one or more omitted obtaining component 610, rendering engine component 612, simulating component 614, interfacing component 616, parameterizing component 620, notifying component 622 and/or recording component 624.

Turning now to the components and also to FIG. 9 in combination with FIG. 6, the obtaining component 610 can locate, search for, download, receive, request and/or otherwise obtain build data 915 with which rendering can be performed by the rendering engine component 612. The build data 915 can comprise data and/or metadata in any suitable format and can be located at any suitable storage component, memory and/or database, without being limited thereto, communicatively coupled to the IDVEG system 602.

In one or more embodiments, the build data 915 can define, describe, bound, limit and/or otherwise be configured for use in construction of any one or more of a three-dimensional simulation 903 of a simulated light source 904, simulated imaging device 901, simulated chamber 906, simulated sample support 908, simulated sample 910 and/or simulated tool 912. In one or more embodiments, the build data 915 can define, describe, bound, limit and/or otherwise be configured for use in virtual construction of a digital twin of a NVS imaging device, also herein referred to as a real-world imaging device. As used here, the term “digital twin” can refer to a replication of and/or at least partially similar virtual re-creation (e.g., rendering) of an imaging device, whether existing or non-existing in the real world.

Using the build data 915, the rendering engine component 612 can render a virtual environment 902 comprising a three-dimensional simulation 903 of a simulated imaging device 901 comprising a simulated chamber 906 having a simulated object (e.g., simulated sample support 908, simulated sample 910 and/or simulated tool 912, without being limited thereto) for analysis being rendered therein. Indeed, each of these aspects can be rendered separately from one another such as to be moveable, manipulatable, modifiable and/or parameterized relative to one another.

In one or more embodiments, the interfacing component 616 can provide interfacing between the IDVEG system 602 and one or more external aspects, including the build data 915, NVS imaging device 631 by way of the imaging device server 632, the imaging device automation and control (AAC) component 634, such as by way of the imaging device server 632, the computing device 400 and display device 410, and/or the set of controls 640.

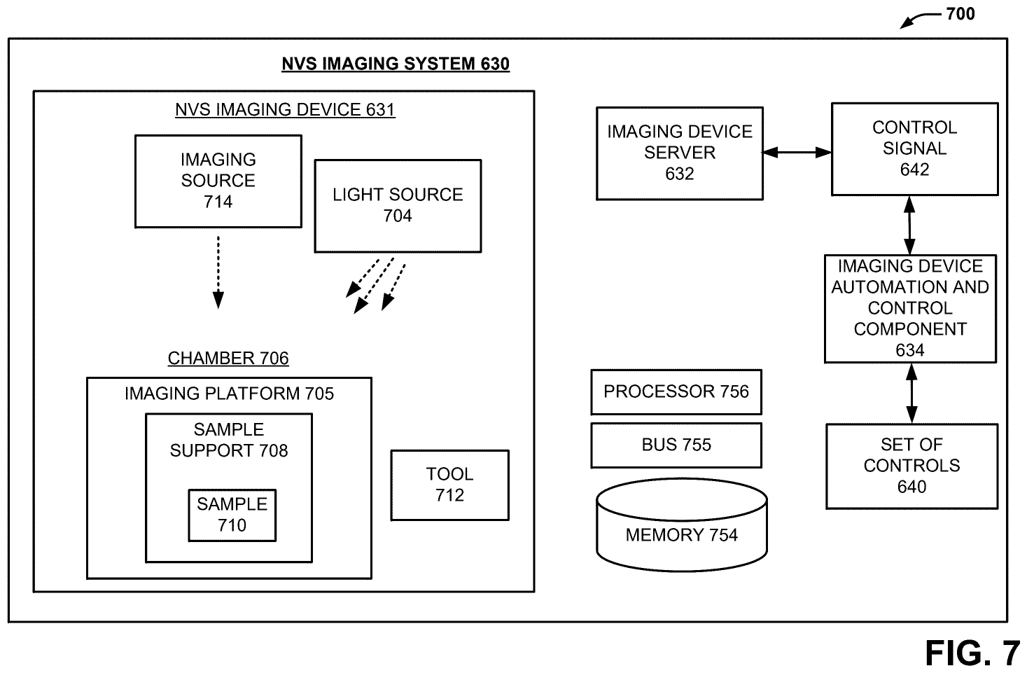

For example, referring briefly to block diagram 700 of FIG. 7, to aid the rendered 3D simulation 903, the interfacing component 916 can map a physical aspect of physical hardware of a non-virtually-simulated (NVS) imaging device 631, of an imaging system 630, to a corresponding rendered aspect of the 3D simulation 903. That is, the interfacing component 916 can, in one or more embodiments, assign a correspondence tag or other metadata, corresponding to a NVS imaging source 714, light source 704, chamber 706, imaging platform 705, sample support 708, sample 710 and/or tool 712 (e.g., the physical aspects of physical hardware), to a rendered aspect having been, to be and/or in the process of being rendered by the rendering engine component 612. Such mapping, and more particularly, a correspondence tag, can be based on the build data 915. As used herein, the term “rendered aspect” can refer to any of the simulated chamber 906, simulated sample support 908, simulated sample 910 and/or simulated tool 912, without being limited thereto.

In one or more embodiments, the correspondence tag can additionally and/or alternatively correspond to one or more aspects of build data 915 corresponding to the particular physical aspect. In this way, a change in build data 915 can allow for a revised rendering of a particular physical aspect by the rendering engine component 612 upon re-access to the build data 915. Reading actions by the rendering engine component 612 of the build data 915 can be performed periodically, on demand and/or at any suitable interval and/or trigger.

Briefly, and without being limited thereto, the imaging system 630 can be and/or comprise an optical microscope, an electron microscope (EM), such as a scanning electron microscope (SEM) or transmission electron microscope (TEM), and/or a focused ion beam (FIB) device. The imaging system 630 can comprise, among other features, one or more physical aspects of physical hardware such as a light source 704, imaging source 714, chamber 706, imaging platform 705, sample support 708, sample 710 and/or tool 712. In one or more embodiments, a tool 712, light source 704 and/or imaging platform 705 can be moveable, such as automatically movable by one or more automation physical hardware aspects, such as via control from the imaging device AAC component 634 via the imaging device server 632. For example, the imaging device AAC component 634 can send one or more control signals 642 to control a single process, on demand process and/or process flow of one or more processes to control any physical aspect of the imaging device 631. It is noted that the imaging device AAC component 634 can be operatively coupled to a suitable processor to allow for automatic control and/or one or more controls of a set of controls 640 can be operatively coupled to the imaging device AAC component 634 to facilitate control of the imaging device 631/imaging system 630 by an entity.

The imaging system 630 can comprise a processor 756, memory 754 and/or bus 755. For sake of brevity, description provided above relative to the processor 606, memory 604 and bus 605 is equally applicable to the processor 756, memory 754 and bus 755.

Turning again to the rendering engine component 612, in one or more embodiments, the rendering engine component 612 can employ 3D voxel grid to model 3D Structure and/or simulated material behavior. As used herein, a “voxel grid” can refer to a grid of voxels that represent values on a grid in a 3D space. IN one or more embodiments, a position of a voxel can be inferred using position of other voxels, such as neighboring voxels, rather than encoding individual voxels with coordinate data or rather than mapping coordinate metadata to the voxels. For example, a voxel can comprise information about the voxel's material properties and can behave in accordance with its surrounding voxels, such as due to the inferred positioning.

In one or more embodiments, a topology of one or more aspects of the 3D simulation 903 can be generated by the rendering engine component 612 using ray-marching and/or a similar algorithm to prevent rigid lines from the voxel grid from being displayed and thus visualized by the end-user. As used herein, “ray-marching” can refer to a class of rendering methods using rays that are divided into smaller ray segments by traversing the rays iteratively. As used herein, a “ray” can refer to a rendered geometrical model of light or other source.

Further, to facilitate one or more of the processes that can be performed by the rendering engine component 612, the obtaining component 610 can read out how the end-user entity, such as a human, automation process, or other entity as described herein, applied a sample modification pattern inside the user interface. Such application could have been made by use of the setting region 308 of the GUI 300 (FIG. 3) and/or the interface device 406/display device 410 of the computing device 400 (FIG. 4). In connection therewith, the obtaining component 610 can identify a simulated beam choice (e.g., FIB, EM, TEM, SEM, etc.) to apply the pattern. This choice can be made by the obtaining component 610 and/or by the end-user entity. In view of the above, the rendering engine component 612 can employ respective information output by the obtaining component 610 to project the pattern into the 3D simulation 903. Subsequently, the rendering engine component 612 can employ a vector characterized by and/or characterizing the simulated beam to simulate a direction of beam particle impact on the simulated sample 910 or other aspect of the 3D simulation 903. In connection therewith, the rendering engine component 612 can generate a corresponding modification of a simulated material of the simulated sample 910 or other aspect of the 3D simulation 903. In one or more embodiments, the rendering engine component 612 can apply the corresponding modification using the underlying 3D voxel grid.

Turning now to the simulating component 614, this component can generate simulation data 650 corresponding to a directed interaction of the 3D simulation 903. For example, a directed interaction can comprise a 3D modification (e.g., movement, addition of material, deletion of material, movement of material thereof) of the simulated sample 910.

Regarding the directed interaction, for example, turning to FIG. 10, and the images 1002-1008 illustrated there, a directed interaction can comprise directing of a simulated ion stream or laser 1010 at a simulated imaging platform 905 (image 1002) and/or modification and/or placement of a sample support 908 and/or simulated sample 910 by a simulated tool 912 (images 1004-1008).

For further example, turning to FIG. 11, and the images 1102-1108 illustrated there, a directed interaction can comprise directing of a simulated ion stream or laser 1010 at a simulated imaging platform 905 (image 1102) and/or modification and/or placement of a sample support 908 and/or simulated sample 910 by a simulated tool 912 (images 1104-1108).

The simulation data 650 can define, describe, bound, limit and/or otherwise provide record of one or more interactions, modifications, manipulations and/or movements of any simulated aspect of the 3D simulation 903 including, but not limited to, the simulated chamber 906, simulated light source 904, simulated sample support 908, simulated sample 910 and/or simulated tool 912. The simulation data 650 can be output and/or made available by the interfacing component 616 to allow for back-and-forth communication between the IDVEG system 602 and the imaging device AAC component 634.

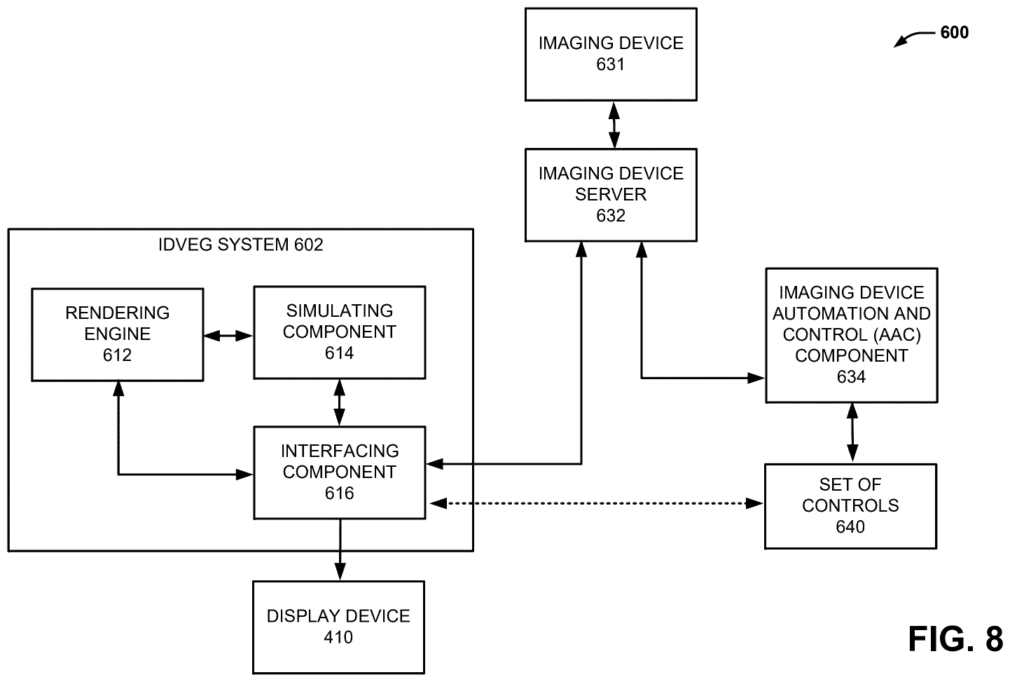

That is, turning now to FIG. 8 and to the interfacing component 616 and imaging device AAC component 634, description is provided regarding one or more processes via which control and/or outputs of the IDVEG 602 are facilitated relative to a abridged block diagram of the non-limiting system 600.

Generally, the IDVEG system 602 can interface with an imaging device AAC component 634. In one or more embodiments, the imaging device AAC component 634 can be at least partially employed to existingly control a NVS imaging device 631 by way of communications therebetween using an imaging device server 632 operatively coupled to the NVS imaging device 631 and its respective physical hardware. In such existing approach, the imaging device AAC 634 can autonomously control the NVS imaging device 631, such as by controlling a process flow of one or more processes to be performed by the one or more physical aspects. In one or more embodiments, a set of controls 640 can be operated by an administrating entity or other entity to provide feedback and/or control of the NVS imaging device 631.

Differently, by output from the interfacing component 616, the imaging device AAC 634 can similarly be employed to provide control with and/or interact with the virtual environment 902. That is, the imaging device AAC 634 can interpret the simulation data 650 as physical hardware feedback data of physical hardware of the non-virtually-simulated imaging device 631. In this way, the IDVEG 602 can be integrated with an existing imaging system 630, with or without a physical imaging device 631 being coupled thereto.

To provide further detail, still with reference to FIG. 8, the rendering engine component 612 can render the virtual environment 902 comprising the initially simulated imaging device 901, based at least partially on the build data 915. The rendering engine 612 further can render one or more three-dimensional changes to the simulated imaging device 901, such as moving, rotating, translating, enlarging, reducing, removing and/or adding one or more portions of the simulated imaging device 901.

These three-dimensional changes can be viewed using at least a full six degrees of freedom of virtual visualization, such as using the computer device 400 including the display device 410 and/or interface device 406. For example, display data can be sent to a GUI or other display device 410 by the interfacing component 616.

The one or more 3D changes to the simulated imaging device 901, as rendered by the rendering engine component 612, can be based on one or more control signals 642 obtained by the interfacing component 616. In one or more embodiments, one or more control signals 642 can comprise data comprising instructions for a change to the 3D simulation 903. In one or more embodiments, one or more control signals 642 can be based on an entity interaction with a set of controls 640 providing feedback directly to the IDVEG system 602. In one or more embodiments, one or more control signals 642 can be provided from the set of controls 640, such as based on entity interaction, but employing the imaging device AAC component 634 as a middle component. In one or ore embodiments, one or more control signals 642 can be provided autonomously and/or automatically from the imaging device AAC component 634. In these ways, the imaging device AAC component 634 can provide for back-and-forth communication between the imaging device AAC component 634 and the IDVEG 602.

Regarding such back-and-forth communication between the imaging device AAC component 634 and the IDVEG 602 (e.g., by use of the interfacing component 616), the imaging device AAC component 634 can obtain feedback from the IDVEG 602 (such as simulation data 650 from the interfacing component 616) to facilitate a next autonomous, automatic and/or user-entity-driven communication to the IDVEG 602 for further modification of the rendered 3D simulation 903. In one or more embodiments, the imaging device AAC component 634 can interpret the feedback from the IDVEG 602 as coming from the NVS imaging device 631 (e.g., via the imaging device server 632).

For example, the simulation data 650 can comprise data corresponding to (e.g., describing and/or defining) a modification to the 3D simulation 903, such as an addition or removal from a simulated sample 910 by simulated interaction of a simulated tool 912 with the simulated sample 910.

For another example, the simulation data 650 can comprise data corresponding to (e.g., describing and/or defining) a reaction caused by a modification to the 3D simulation 903. In one or more embodiments, such reaction can comprise a simulated touch interaction, simulated undesired movement (e.g., a drop) or simulated material, and/or a simulated failure of a workflow, among other examples. A touch interaction can be an undesired contiguous rendering of a pair of simulated elements with one another, such as an unintended simulated tool/simulated chamber, simulated tool/simulated chamber wall and/or simulated sample/simulated chamber wall interaction. A failure of a workflow can comprise in ability to proceed with a next simulated step, such as a movement or modification, which failure can be cause by an undesired touch, limit and/or impediment based on simulation data 650, underlying coding and/or simulated material interaction within the 3D simulation 903.

For yet another example, the simulation data 650 can comprise data corresponding to (e.g., describing and/or defining) a change of a parameter, such as an imaging parameter 672. As used herein the parameter 672 can comprise, but is not limited to light intensity, imaging voltage and/or resultant image noise.

Based on the simulation data 650, in one or more embodiments, one or more control signals 642 can be generated by the imaging device AAC component 634 corresponding to (e.g., describing and/or defining) a modification to the 3D simulation 903

The interpretation by the imaging device AAC component 634 can be facilitated by operative coupling of the IDVEG system 602 to the imaging device server 632 and facilitation of the back-and-forth communication between the imaging device AAC component 634 and the IDVEG system 602 using the imaging device server 632. In this way, the imaging device AAC 634 can assume interaction with a NVS imaging device 631 instead of the IDVEG system 602. Accordingly, a realistic interaction with the simulated imaging device 901 and with the set of controls 640 can be facilitated for any of various purposes of learning, training, testing, teaching, presentation and/or the like, without the need for an NVS imaging device 631 coupled thereto. That is, the coupling of the NVS imaging device 631 to the imaging device server 632 as illustrated at FIG. 8 can be optional.

It is noted that in one or more embodiments, the set of controls 640 employed can be a same set of controls 640 employed for a physical twin NVS imaging device 640. In one or more other embodiments, the set of controls 640 can at least partially replicate a set of controls 640 that is employed for the physical twin NVS imaging device 640.

For further example, in one or more embodiments, the imaging device AAC 634 and IDVEG system 602 can, in combined coordination, support imaging simulation and/or can be capable of modifying the 3D simulation 903 or the virtual environment 902.

That is, in one or more embodiments, the imaging device AAC 634 and IDVEG 602 each can support processes comprising both SEM & FIB deposition and milling from the electron microscopy features. These processes can comprise simulation of operations such as lifting out a chunk (e.g., of lamella) from the simulated sample 910 using a simulated tool 912, such as a manipulator (e.g., an easy-lift tool) and attaching the chunk to another simulated tool 912, such as a lamella carrier (LC). These processes can comprise, on the simulated LC, performing a final simulated thinning of the chunk to reduce lamella thickness.

In one or more embodiments, the IDVEG 602 combination can support generation and/or modification of, and the imaging device AAC 634 can support modification of, various simulated samples 910 simulated materials at different depths and/or thicknesses of the simulated samples 910. This can allow for measuring sample thickness, layer thickness, layer separation and/or a similar metrology of the simulated samples 910. This also can allow for a simulated sample modification process, generated by the IDVEG 602, where a final transmission electron microscope (TEM) lamella preparation process can closely resemble a real-world process.

Additionally, and/or alternatively in connection therewith, the interfacing component 616 can, based on process flow data corresponding to a process flow being performed at physical hardware of a non-virtually-simulated imaging device, direct, within the virtual environment 902, rendering of a simulated test of a subsequent action to be performed at the physical hardware of a non-virtually-simulated imaging device. For example, the process flow data can be provided via one or more signals 642 to the IDVEG 602. The one or more signals 642 can thus define build data 915 and/or simulation data 650, among other types of data. Based on a subsequent rendering by the rendering engine component 612 in response to obtaining of the one or more signals 642 by the interfacing component 616, a 3D simulation 903 of the real-world test can be rendered. Subsequent thereto, the one or more back-and-forth communications between the IDVEG 602 and the imaging device AAC 634 can proceed to allow for execution, by the IDVEG system 602 of a simulated subsequent action at least partially before and/or at least partially at the same time as the subsequent action is performed at the NVS imaging device 631. In one or more embodiments, the imaging device AAC 634 can be the same and/or different AAC being employed for the real world NVS imaging device 631.

Turning now to additional control of the virtual environment 902 and to additional components of the IDVEG system 602, the parameterizing component 620 can simulate a change to an imaging device parameter changing a state of the virtual environment to correspond to a selectable change of state of a chamber of a non-virtually-simulated imaging device. These parameters can comprise, but are not limited to light intensity, imaging voltage and/or resultant image noise. In this way, configurable testing environments within a simulated chamber 906 can be provided for.

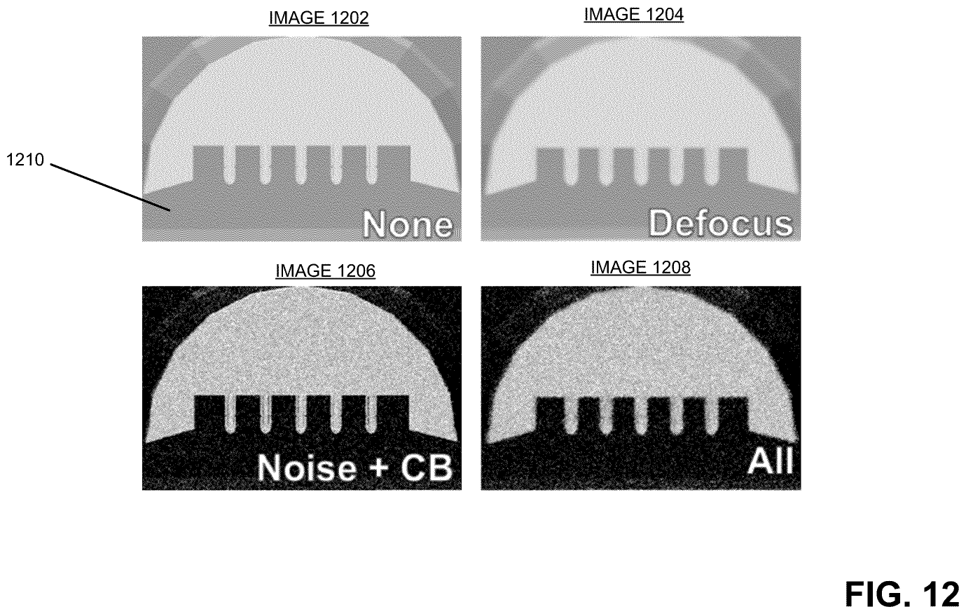

For example, turning to FIG. 12, various real world image qualities can be simulated relative to a simulated object 1210 being rendered and displayed, such as a defocused image (image 1204), noisy image (image 1206) and/or defocused and noisy image (image 1208).

In one or more embodiments, the parameterizing component 620 can provide one or more aspects of error injection into the 3D simulation 903, such as to purposely cause defocus, image drift and/or noise. In the real world, these aspects of error could be caused by any one or more of physical vibration, signal noise, voltage noise, image processing and/or conflicting signal. In this way, the IDVEG 602 can replicate (e.g., simulate) bad parameters, causes and/or environments.

Furthermore, in one or more embodiments, the parameterizing component 620, based on historical data and/or analysis of an image of the 3D simulation 903, can generate a suggestion of a parameter to employ, such as to reduce one or more of defocus, image drift and/or noise and/or to improve one or more of clarity and/or focus. Historical data can be stored at any suitable location such as the memory 604 and/or any other database communicatively coupled to the IDVEG system 602.

The notifying component 622 can generate a notification 660 of a failure of a simulated workflow within the virtual environment or of a simulated touch interaction with a simulated element within the simulated chamber. Such notification 660 can be provided to an entity, such as by way of a device corresponding to the entity, such as the computer device 400. A notification 660 can comprise any one or more of an audible and/or textual aspect.

With respect to such notification 660, as indicated above, a touch interaction can be an undesired contiguous rendering of a pair of simulated elements with one another, such as an unintended simulated tool/simulated chamber, simulated tool/simulated chamber wall and/or simulated sample/simulated chamber wall interaction. A failure of a workflow can comprise inability to proceed with a next simulated step, such as a movement or modification, which failure can be cause by an undesired touch, limit and/or impediment based on simulation data 650, underlying coding and/or simulated material interaction within the 3D simulation 903. That is, there can be a high quantity of image processing, stage movement, rotations, etc. associated with an NVS process flow, and thus likewise associated virtually with a virtual simulation of such process flow. Accordingly, one or more such steps can fail, such as from a code writing standpoint.

Next, the recording component 624 can generate and/or update a data record (e.g., build data 915 and/or associated mapping, tag and/or the like) associated with the 3D simulation 603. This recording process can comprise tagging, marking and/or otherwise writing data to a respective build data 915, mapping, tag and/or the like such as via an appropriate write action.

As mentioned above, build data 915 can be provided in any suitable format (e.g., log, table, matrix, data, metadata, etc.) and can be stored at any suitable location that is communicatively accessible by the IDVEG system 602 (e.g., at the memory 604, without being limited thereto).

In one or more embodiments, the recorded data can be employed as the aforementioned historical data by the parameterizing component 620.

In view of the above one or more processes that can be performed by the one or more components of the IDVEG system 602, various benefits can be provided as compared to existing frameworks.

These benefits are additionally described above and/or below and can comprise providing a greater quantity of and more efficient access to an imaging device.

In one or more cases, by the use of the 3D simulation 903, more rotations and views of the simulated chamber 906 and the contents therein can be obtained than are enabled in an NVS imaging device 631. For example, an NVS imaging device 631 can have approximately up to four cameras aimed only at a respective imaging device stage. Such cameras cannot, for example, look back at one or more columns of the imaging device 631.

In one or more cases, the 3D simulation and back-and-forth control between the IDVEG system 602 and an imaging device AAC component 634 can allow for process flow development, process flow testing, interaction testing, material placement testing, material removal testing and/or the like with all being simulated three-dimensionally to provide for accurate and real-world-similar results. These results can include process flow feedback and/or notifications, touch interaction feedback and/or notifications, material placement and/or removal accuracy, and/or the like.

In one or more cases, the 3D simulation and back-and-forth control between the IDVEG system 602 and an imaging device AAC component 634 can allow for any one or more of learning, training, studying, experimenting and/or presenting relative to an imaging device without use of a physical NVS imaging device. More detailed examples can include presentation of a device and/or physical hardware before being available for NVS testing, testing of process development code, replication of experimentation, such as for use as a control, and/or the like.

It is noted that in one or more embodiments, any one or more of the processes described above and/or below as being performed by the obtaining component 610, rendering engine component 612, simulating component 614, interfacing component 616, parameterizing component 620, notifying component 622 and/or recording component 624 can be performed external to the IDVEG system 602 and/or non-limiting system 600.

It also is noted that in one or more embodiments, any one or more of the processes discussed above as being performed by the non-limiting system 600 can be performed automatically in succession and/or at least partially at the same time as one another.

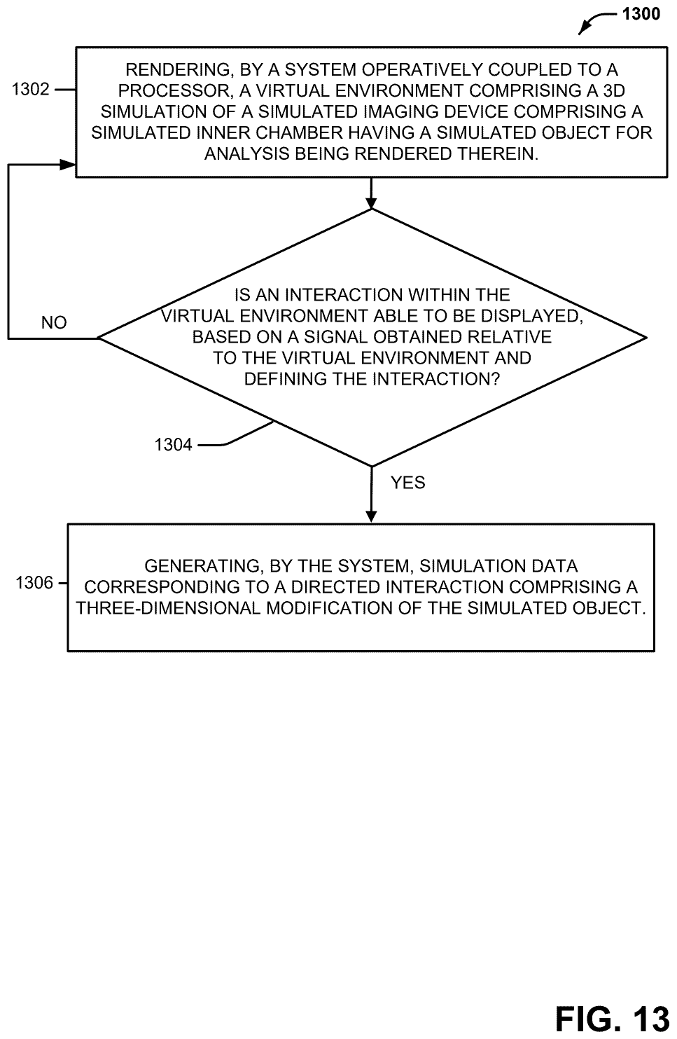

As a summary of the above-described components and functions thereof, referring next to FIG. 13, illustrated is a flow diagram of an example, non-limiting method 1300 that can facilitate imaging device virtual simulation, in accordance with one or more embodiments described herein, such as the non-limiting system 600 of FIG. 6. While the non-limiting method 1300 is described relative to the non-limiting system 600 of FIG. 6, the non-limiting method 1300 can be applicable also to other systems described herein, such as the non-limiting system 500 of FIG. 5. Repetitive description of like elements and/or processes employed in respective embodiments is omitted for sake of brevity.

At 1302, the non-limiting method 1300 can comprise rendering, by a system operatively coupled to a processor (e.g., rendering engine component 512 coupled to processor 606), a virtual environment (e.g., virtual environment 902) comprising a 3D simulation (e.g., 3D simulation 903) of a simulated imaging device (e.g., simulated imaging device 901) comprising a simulated chamber (e.g., simulated chamber 906) having a simulated object (e.g., simulated sample 910, simulated sample support 908 and/or simulated tool 912) for analysis being rendered therein.

At 1304, the non-limiting method 1300 can comprise determining, by the system (e.g., interfacing component 616), whether an interaction (e.g., as illustrated at FIGS. 10 and 11) within the virtual environment is able to be displayed, based on a signal obtained relative to the virtual environment and defining the interaction. If yes, the non-limiting method 1300 can proceed to step 1306. If no, the non-limiting method can proceed back to step 1302 to continue to render the virtual environment as is (e.g., without the interaction).

At 1306, the non-limiting method 1300 can comprise generating, by the system (e.g., simulating component 614), simulation data (e.g., simulation data 650) corresponding to a directed interaction (e.g., as illustrated at FIGS. 10 and 11) comprising a three-dimensional modification (e.g., as illustrated at FIGS. 10 and 11) of the simulated object.

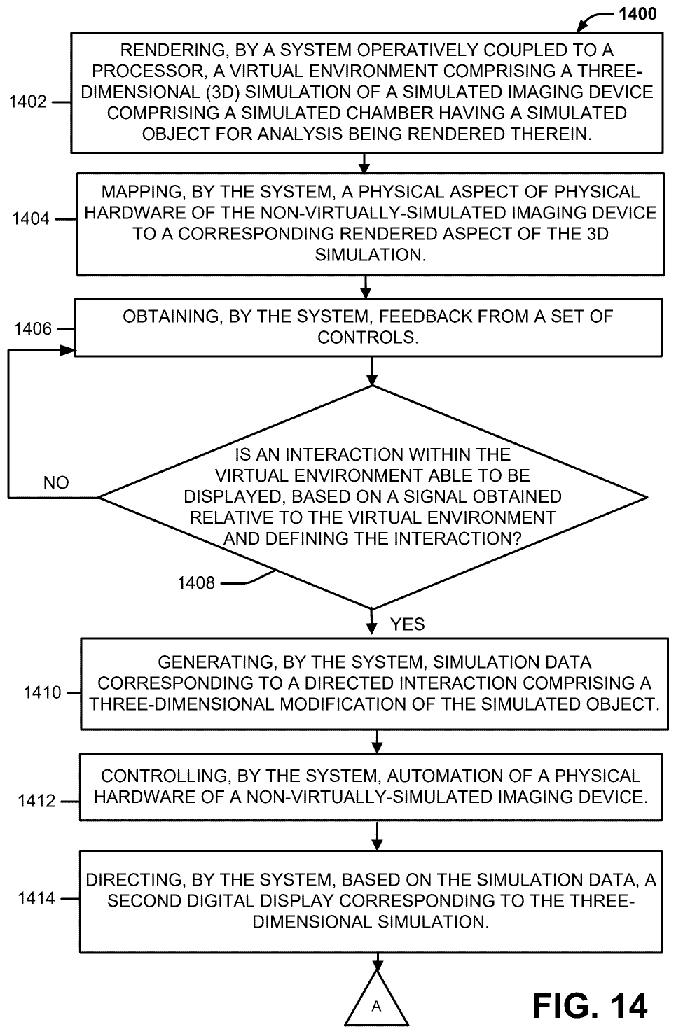

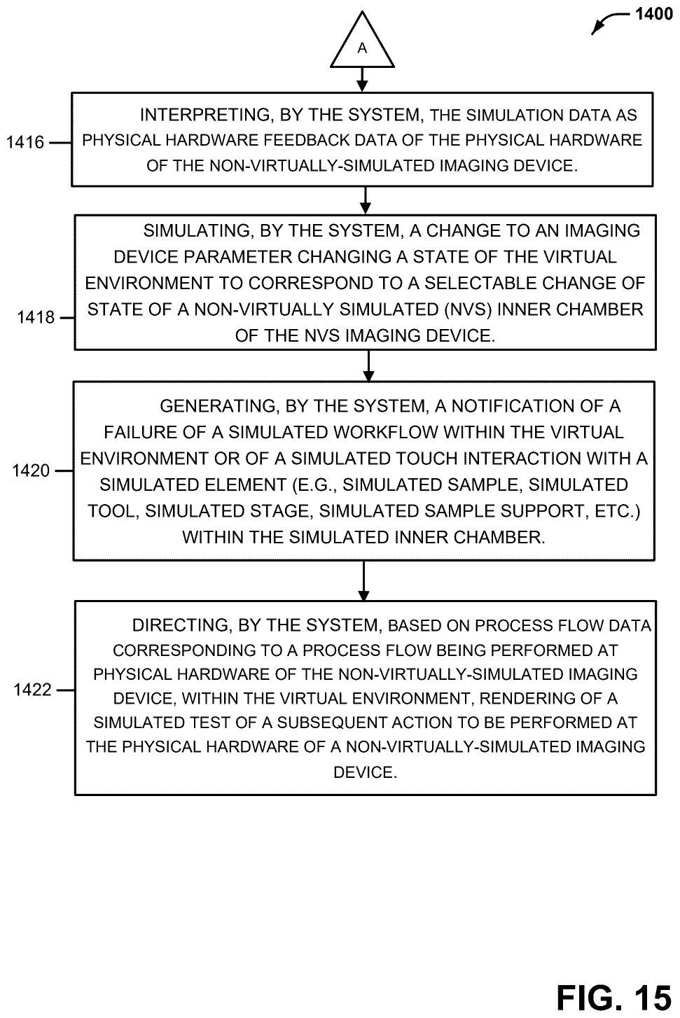

As another summary of the above-described components and functions thereof, referring next to FIGS. 14 and 15, illustrated is a flow diagram of an example, non-limiting method 1400 that can facilitate imaging device virtual simulation, in accordance with one or more embodiments described herein, such as the non-limiting system 600 of FIG. 6. While the non-limiting method 1400 is described relative to the non-limiting system 600 of FIG. 6, the non-limiting method 1200 can be applicable also to other systems described herein, such as the non-limiting system 500 of FIG. 5. Repetitive description of like elements and/or processes employed in respective embodiments is omitted for sake of brevity.

At 1402, the non-limiting method 1400 can comprise rendering, by a system operatively coupled to a processor (e.g., rendering engine component 612 coupled to processor 606), a virtual environment (e.g., virtual environment 902) comprising a three-dimensional (3D) simulation (e.g., 3D simulation 903) of a simulated imaging device (e.g., simulated imaging device 901) comprising a simulated chamber (e.g., simulated chamber 906) having a simulated object for analysis being rendered therein.

At 1404, the non-limiting method 1400 can comprise mapping, by the system (e.g., interfacing component 616), a physical aspect (e.g., NVS imaging device 631, imaging source 714, light source 704, chamber 706, imaging platform 705, sample support 708, sample 710 and/or tool 712) of physical hardware of the non-virtually-simulated imaging device to a corresponding rendered aspect (e.g., simulated light source 904, simulated imaging device 901, simulated chamber 906, simulated sample support 908, simulated sample 910 and/or simulated tool 912) of the three-dimensional simulation.

At 1406, the non-limiting method 1400 can comprise obtaining, by the system (e.g., interfacing component 616), feedback (e.g., control signal 642) from a set of controls (e.g., controls 640).

At 1408, the non-limiting method 1400 can comprise determining, by the system (e.g., interfacing component 616), whether an interaction (e.g., as illustrated at FIGS. 10-12) within the virtual environment is able to be displayed, based on the signal obtained relative to the virtual environment and defining the interaction. If yes, the non-limiting method 1400 can proceed to step 1410. If no, the non-limiting method can proceed back to step 1406 to continue to generate the virtual environment as is (e.g., without the interaction).

At 1410, the non-limiting method 1400 can comprise generating, by the system (e.g., simulating component 614), simulation data (e.g., simulation data 650) corresponding to a directed interaction comprising a three-dimensional modification (e.g., as illustrated at FIGS. 10 and 11) of the simulated object.

At 1412, the non-limiting method 1400 can comprise controlling, by the system (e.g., imaging device automation and control component 634), automation of the physical hardware of the non-virtually-simulated imaging device.

At 1414, the non-limiting method 1400 can comprise directing, by the system (e.g., imaging device AAC component 634), based on the simulation data, a second digital display (e.g., as illustrated at FIGS. 10 and 11) corresponding to the three-dimensional simulation.

At 1416, the non-limiting method 1400 can comprise interpreting, by the system (e.g., imaging device AAC component 634), the simulation data as physical hardware feedback data of the physical hardware of the non-virtually-simulated imaging device.

At 1418, the non-limiting method 1400 can comprise simulating, by the system (e.g., parameterizing component 620), a change to an imaging device parameter (e.g., parameter 672) changing a state of the virtual environment to correspond to a selectable change of state of a non-virtually-simulated chamber (e.g., chamber 706, such as an inner chamber) of the non-virtually-simulated imaging device (e.g., NVS imaging device 631).

At 1420, the non-limiting method 1400 can comprise generating, by the system (e.g., notifying component 618), a notification (e.g., notification 660) of a failure of a simulated workflow within the virtual environment or of a simulated touch interaction with a simulated element (e.g., simulated sample, simulated tool, simulated stage, simulated sample support, etc.) within the simulated chamber.

At 1422, the non-limiting method 1400 can comprise directing, by the system (e.g., interfacing component 616), based on process flow data corresponding to a process flow being performed at physical hardware of the non-virtually-simulated imaging device, within the virtual environment, rendering of a simulated test of a subsequent action to be performed at the physical hardware of a non-virtually-simulated imaging device.

### Additional Summary

For simplicity of explanation, the computer-implemented and non-computer-implemented methodologies provided herein are depicted and/or described as a series of acts. It is to be understood that the subject innovation is not limited by the acts illustrated and/or by the order of acts, for example acts can occur in one or more orders and/or concurrently, and with other acts not presented and described herein. Furthermore, not all illustrated acts can be utilized to implement the computer-implemented and non-computer-implemented methodologies in accordance with the described subject matter. In addition, the computer-implemented and non-computer-implemented methodologies could alternatively be represented as a series of interrelated states via a state diagram or events. Additionally, the computer-implemented methodologies described hereinafter and throughout this specification are capable of being stored on an article of manufacture for transporting and transferring the computer-implemented methodologies to computers. The term article of manufacture, as used herein, is intended to encompass a computer program accessible from any computer-readable device or storage media.

The systems and/or devices have been (and/or will be further) described herein with respect to interaction between one or more components. Such systems and/or components can include those components or sub-components specified therein, one or more of the specified components and/or sub-components, and/or additional components. Sub-components can be implemented as components communicatively coupled to other components rather than included within parent components. One or more components and/or sub-components can be combined into a single component providing aggregate functionality. The components can interact with one or more other components not specifically described herein for the sake of brevity, but known by those of skill in the art.

In summary, one or more systems, computer program products and/or computer-implemented methods provided herein relate to a process for imaging device virtual simulation, e.g., virtually simulating an imaging device or portion thereof to serve as a digital twin of an existing NVS imaging device or to serve as a purely standalone virtually-simulated imaging device, without being limited thereto.

A system provided herein comprises a memory 504, 604 that stores computer executable components, and a processor 506, 606 that executes the computer executable components stored in the memory 504, 604, wherein the computer executable components comprise a rendering engine component 512, 612 that renders a virtual environment 902 comprising a three-dimensional simulation 903 of a simulated imaging device 901 comprising a simulated chamber 906 having a simulated object (e.g., 908, 910, 912) for analysis being rendered therein, and a simulating component 614 that generates simulation data 650 corresponding to a directed interaction comprising a three-dimensional modification of the simulated object (e.g., 908, 910, 912).

The one or more embodiments disclosed herein can allow for ability to learn, train, study, experiment with and/or otherwise employ imaging device techniques with or without the use of the respective imaging device (also herein referred to as a non-virtually-simulated (NVS) imaging device or live imaging device). Interactions within the simulated chamber provided by the one or more embodiments described herein can allow for modification of a simulated sample (e.g., sample grid, lamella, etc.), movement of a simulated sample, work on a simulated sample with a simulated tool, etc., while simulating the precise movement conditions of the respective imaging device. Indeed, the one or more embodiments described herein can be employed to test control software or code while providing notification of work process failure or touch alarms, among other notifications, without the use of a respective imaging device.

The one or more embodiments described herein can allow for use of a set of controls being at least partially the same as, and/or replicating, a device set of controls of the non-virtually-simulated imaging device. In this way, a method and/or technique of using a NVS imaging device can be directly employed with the simulated imaging device as generated by the one or more embodiments described herein.

Indeed, in view of the one or more embodiments described herein, a practical application of the one or more systems, computer-implemented methods and/or computer program products described herein can be ability to employ the one or more embodiments described herein in conjunction with (e.g., communicatively coupled to) an automation and/or control (AAC) application that is otherwise employed to automate and/or control a NVS imaging device. In such cases, back and forth feedback can be provided between the one or more embodiments described herein, regarding the simulation, and the AAC component. That is, this back-and-forth feedback can be employed in place of existing back and forth feedback between a NVS imaging device server and the AAC component. Accordingly, the AAC component can provide input to the one or more embodiments described herein to control a respective simulation in place of the AAC component controlling the NVS imaging device. Likewise, the one or more embodiments described herein can provide output as feedback to the AAC component, in place of receipt of feedback at the AAC component from a NVS imaging device server.

In connection with the above, the one or more embodiments described herein can provide for parameterization within a simulated environment that replicates and/or is similar to available parameterization of a NVS imaging device. Parameters that can be simulated by the one or more embodiments described herein can comprise, but are not limited to, lighting, imaging voltage and/or resultant image noise. Furthermore, such parameters can comprise error injection parameters, such as to simulate one or more flaws of physical hardware of a NVS imaging device, such as, but not limited to, image drift.

Further, in one or more cases, the one or more embodiments described herein can be employed during execution of a use of a NVS imaging device (e.g., setup, test, experiment, etc.). For example, an interaction generated by the one or more embodiments described herein can allow for a simulated test of a subsequent action to be performed at the NVS imaging device.

Furthermore, one or more embodiments described herein can be employed in a real-world system based on the disclosed teachings. For example, as noted above, the use of a system described herein can result in a less expensive, less costly (e.g., power, time, resource bandwidth) and more efficient framework for any or almost any use of a NVS imaging device that does not require use of a real-world sample. Rather, a virtual simulated sample can be employed for any one or more of training, learning, testing, process flow testing, code testing and/or the like relative to a system for operating a NVS imaging device, such as an AAC component 634. That is, the one or more embodiments described herein can provide for high realism and high similarity of a real-world NVS imaging device through the alternative generation of a virtual environment 902 comprising a simulated imaging device 901 (or put another way, a 3D simulation 903 of a simulated chamber 906). The embodiments disclosed herein thus can provide improvements to scientific instrument technology (e.g., improvements in the computer technology supporting such scientific instruments, among other improvements), not least of which includes making the processes and/or controls corresponding to a NVS imaging device more readily available.

The systems and/or devices have been (and/or will be further) described herein with respect to interaction between one or more components. Such systems and/or components can include those components or sub-components specified therein, one or more of the specified components and/or sub-components, and/or additional components. Sub-components can be implemented as components communicatively coupled to other components rather than included within parent components. One or more components and/or sub-components can be combined into a single component providing aggregate functionality. The components can interact with one or more other components not specifically described herein for the sake of brevity, but known by those of skill in the art.

One or more embodiments described herein can be, in one or more embodiments, inherently and/or inextricably tied to computer technology and cannot be implemented outside of a computing environment. For example, one or more processes performed by one or more embodiments described herein can more efficiently, and even more feasibly, provide program and/or program instruction execution, such as relative to virtual simulation of an imaging device as compared to existing systems and/or techniques using manual approaches and/or computer-aided approaches. Systems, computer-implemented methods and/or computer program products providing performance of these processes are of great utility in the fields of material analysis, such as in material analysis related to use of an imaging device, such as a microscope, or more particularly a dual beam system, and cannot be equally practicably implemented in a sensible way outside of a computing environment.

One or more embodiments described herein can employ hardware and/or software to solve problems that are highly technical, that are not abstract, and that cannot be performed as a set of mental acts by a human. For example, a human, or even thousands of humans, cannot efficiently, accurately and/or effectively automatically generate, modify, and/or provide virtual interaction within a virtual environment relating to an imaging device simulated chamber (906) as the one or more embodiments described herein can provide this process. That is, regardless of use of a microscope and manual viewing approaches, a human simply cannot digitize a virtually-simulated chamber performed by the one or more embodiments described herein, as a set of mental acts and/or with pen and paper.

In one or more embodiments, one or more of the processes described herein can be performed by one or more specialized computers (e.g., a specialized processing unit, a specialized classical computer, a specialized quantum computer, a specialized hybrid classical/quantum system and/or another type of specialized computer) to execute defined tasks related to the one or more technologies describe above. One or more embodiments described herein and/or components thereof can be employed to solve new problems that arise through advancements in technologies mentioned above, employment of quantum computing systems, cloud computing systems, computer architecture and/or another technology.

One or more embodiments described herein can be fully operational towards performing one or more other functions (e.g., fully powered on, fully executed and/or another function) while also performing one or more of the one or more operations described herein.

To provide additional summary, a listing of embodiments and features thereof is next provided.

A system, comprising: a memory that stores computer executable components; and a processor that executes the computer executable components stored in the memory, wherein the computer executable components comprise: a rendering engine component that renders a virtual environment comprising a three-dimensional simulation of a simulated imaging device comprising a simulated chamber having a simulated object for analysis being rendered therein; and a simulating component that generates simulation data corresponding to a directed interaction comprising a three-dimensional modification of the simulated object.

The system of the preceding paragraph, wherein the computer executable component further comprise: an interfacing component that maps a physical aspect of physical hardware of a non-virtually-simulated imaging device to a corresponding rendered aspect of the three-dimensional simulation.

The system of any preceding paragraph, wherein the system further comprises: an imaging device automation and control component that controls automation of a physical hardware of a non-virtually-simulated imaging device, wherein the imaging device automation and control component also directs, based on the simulation data, a second digital display corresponding to the three-dimensional simulation.

The system of any preceding paragraph, wherein the imaging device automation and control component interprets the simulation data as physical hardware feedback data of the physical hardware of the non-virtually-simulated imaging device.

The system of any preceding paragraph, wherein the computer executable components further comprise: a notifying component that generates a notification of a failure of a simulated workflow within the virtual environment or of a simulated touch interaction with a simulated element within the simulated chamber.

The system of any preceding paragraph, wherein the computer executable components further comprise: a parameterizing component that simulates a change to an imaging device parameter changing a state of the virtual environment to correspond to a selectable change of state of a chamber of a non-virtually-simulated imaging device.

The system of any preceding paragraph, wherein the computer executable components further comprise: an interfacing component that, based on process flow data corresponding to a process flow being performed at physical hardware of a non-virtually-simulated imaging device, directs, within the virtual environment, rendering of a simulated test of a subsequent action to be performed at the physical hardware of a non-virtually-simulated imaging device.

The system of any preceding paragraph, wherein the computer executable components further comprise: an interfacing component that obtains feedback from a set of controls and that directs rendering of the digital display based on the feedback.

A computer-implemented method, comprising: rendering, by a system operatively coupled to a processor, a virtual environment comprising a three-dimensional simulation of a simulated imaging device comprising a simulated chamber having a simulated object for analysis being rendered therein; and generating, by the system, simulation data corresponding to a digital display of an interaction comprising a three-dimensional modification of the simulated object.

The computer-implemented method of the preceding paragraph, further comprising: mapping, by the system, a physical aspect of physical hardware of a non-virtually-simulated imaging device to a corresponding rendered aspect of the three-dimensional simulation.

The computer-implemented method of any preceding paragraph, further comprising: controlling, by the system, automation of a physical hardware of a non-virtually-simulated imaging device; and directing, by the system, based on the simulation data, a second digital display corresponding to the three-dimensional simulation.

The computer-implemented method of any preceding paragraph, further comprising: interpreting, by the system, the simulation data as physical hardware feedback data of the physical hardware of the non-virtually-simulated imaging device.

The computer-implemented method of any preceding paragraph, further comprising: generating, by the system, a notification of a failure of a simulated workflow within the virtual environment or of a simulated touch interaction with a simulated element within the simulated chamber.

The computer-implemented method of any preceding paragraph, simulating, by the system, a change to an imaging device parameter changing a state of the virtual environment to correspond to a selectable change of state of a chamber of a non-virtually-simulated imaging device.

A computer program product facilitating a process for imaging device virtual simulation, the computer program product comprising a computer readable storage medium having program instructions embodied therewith, and the program instructions executable by a processor to cause the processor to: render, by the processor, a virtual environment comprising a three-dimensional simulation of a simulated object within a simulated chamber of a simulated imaging device; and generate, by the processor, simulation data corresponding to a digital display of an interaction comprising a three-dimensional modification of the simulated object.

The computer program product of the preceding paragraph, wherein the program instructions are further executable by the processor to cause the processor to: map, by the processor, a physical aspect of physical hardware of a non-virtually-simulated imaging device to a corresponding rendered aspect of the three-dimensional simulation.

The computer program product of any preceding paragraph, wherein the program instructions executable by the processor to cause the processor to identify further cause the processor to: control, by the processor, automation of a physical hardware of a non-virtually-simulated imaging device; and direct, by the processor, based on the simulation data, a second digital display corresponding to the three-dimensional simulation.

The computer program product of any preceding paragraph, wherein the program instructions are further executable by the processor to cause the processor to: interpret, by the processor, the simulation data as physical hardware feedback data of the physical hardware of the non-virtually-simulated imaging device.

The computer program product of any preceding paragraph, wherein the program instructions are further executable by the processor to cause the processor to: generate, by the processor, a notification of a failure of a simulated workflow within the virtual environment or of a simulated touch interaction with a simulated element within the simulated chamber.

The computer program product of any preceding paragraph, wherein the program instructions are further executable by the processor to cause the processor to: simulate, by the processor, a change to an imaging device parameter changing a state of the virtual environment to correspond to a selectable change of state of a chamber of a non-virtually-simulated imaging device.

### Scientific Instrument System Description

Turning next to FIG. 16, a detailed description is provided of additional context for the one or more embodiments described herein at FIGS. 1-15. One or more computing devices implementing any of the scientific instrument modules or methods disclosed herein can be part of a scientific instrument system. FIG. 16 illustrates a block diagram of an example scientific instrument system 1600 in which one or more of the scientific instrument methods or other methods disclosed herein can be performed, in accordance with various embodiments described herein. The scientific instrument modules and methods disclosed herein (e.g., the scientific instrument module 100 of FIG. 1 and the method 200 of FIG. 2) can be implemented by one or more of the scientific instrument 1610, the user local computing device 1620, the service local computing device 1630, and/or the remote computing device 1640 of the scientific instrument system 1600.

Any of the scientific instrument 1610, the user local computing device 1620, the service local computing device 1630, and/or the remote computing device 1640 can include any of the embodiments of the computing device 400 discussed herein with reference to FIG. 4, and any of the scientific instrument 1610, the user local computing device 1620, the service local computing device 1630, and/or the remote computing device 1640 can take the form of any appropriate one or more of the embodiments of the computing device 400 discussed herein with reference to FIG. 4.

One or more of the scientific instruments 1610, the user local computing device 1620, the service local computing device 1630, and/or the remote computing device 1640 can include a processing device 1602, a storage device 1604, and/or an interface device 1606. The processing device 1602 can take any suitable form, including the form of any of the processors 402 discussed herein with reference to FIG. 4. The processing devices 1602 included in different ones of the scientific instrument 1610, the user local computing device 1620, the service local computing device 1630, and/or the remote computing device 1640 can take the same form or different forms. The storage device 1604 can take any suitable form, including the form of any of the storage devices 404 discussed herein with reference to FIG. 4. The storage devices 1604 included in different ones of the scientific instrument 1610, the user local computing device 1620, the service local computing device 1630, and/or the remote computing device 1640 can take the same form or different forms. The interface device 1606 can take any suitable form, including the form of any of the interface devices 406 discussed herein with reference to FIG. 4. The interface devices 1606 included in different ones of the scientific instrument 1610, the user local computing device 1620, the service local computing device 1630, and/or the remote computing device 1640 can take the same form or different forms.

The scientific instrument 1610, the user local computing device 1620, the service local computing device 1630, and/or the remote computing device 1640 can be in communication with other elements of the scientific instrument system 1600 via communication pathways 1608. The communication pathways 1608 can communicatively couple the interface devices 1606 of different ones of the elements of the scientific instrument system 1600, as shown, and can be wired or wireless communication pathways (e.g., in accordance with any of the communication techniques discussed herein with reference to the interface devices 406 of the computing device 400 of FIG. 4). The particular scientific instrument system 1600 depicted in FIG. 16 includes communication pathways between each pair of the scientific instrument 1610, the user local computing device 1620, the service local computing device 1630, and the remote computing device 1640, but this “fully connected” implementation is simply illustrative, and in various embodiments, various ones of the communication pathways 1608 can be omitted. For example, in one or more embodiments, a service local computing device 1630 can omit a direct communication pathway 1608 between its interface device 1606 and the interface device 1606 of the scientific instrument 1610, but can instead communicate with the scientific instrument 1610 via the communication pathway 1608 between the service local computing device 1630 and the user local computing device 1620 and/or the communication pathway 1608 between the user local computing device 1620 and the scientific instrument 1610.

The scientific instrument 1610 can include any appropriate scientific instrument, such as a separation or MS instrument, or other instrument facilitating material analysis.

The user local computing device 1620 can be a computing device (e.g., in accordance with any of the embodiments of the computing device 400 discussed herein) that is local to a user of the scientific instrument 1610. In one or more embodiments, the user local computing device 1620 can also be local to the scientific instrument 1610, but this need not be the case; for example, a user local computing device 1620 that is associated with a home, office or other building associated with a user entity can be remote from, but in communication with, the scientific instrument 1610 so that the user entity can use the user local computing device 1620 to control and/or access data from the scientific instrument 1610. In one or more embodiments, the user local computing device 1620 can be a laptop, smartphone, or tablet device. In one or more embodiments the user local computing device 1620 can be a portable computing device. In one or more embodiments, the user local computing device 1620 can deployed in the field.

The service local computing device 1630 can be a computing device (e.g., in accordance with any of the embodiments of the computing device 400 discussed herein) that is local to an entity that services the scientific instrument 1610. For example, the service local computing device 1630 can be local to a manufacturer of the scientific instrument 1610 or to a third-party service company. In one or more embodiments, the service local computing device 1630 can communicate with the scientific instrument 1610, the user local computing device 1620, and/or the remote computing device 1640 (e.g., via a direct communication pathway 1608 or via multiple “indirect” communication pathways 1608, as discussed above) to receive data regarding the operation of the scientific instrument 1610, the user local computing device 1620, and/or the remote computing device 1640 (e.g., the results of self-tests of the scientific instrument 1610, calibration coefficients used by the scientific instrument 1610, the measurements of sensors associated with the scientific instrument 1610, etc.). In one or more embodiments, the service local computing device 1630 can communicate with the scientific instrument 1610, the user local computing device 1620, and/or the remote computing device 1640 (e.g., via a direct communication pathway 1608 or via multiple “indirect” communication pathways 1608, as discussed above) to transmit data to the scientific instrument 1610, the user local computing device 1620, and/or the remote computing device 1640 (e.g., to update programmed instructions, such as firmware, in the scientific instrument 1610, to initiate the performance of test or calibration sequences in the scientific instrument 1610, to update programmed instructions, such as software, in the user local computing device 1620 or the remote computing device 1640, etc.). A user entity of the scientific instrument 1610 can utilize the scientific instrument 1610 or the user local computing device 1620 to communicate with the service local computing device 1630 to report a problem with the scientific instrument 1610 or the user local computing device 1620, to request a visit from a technician to improve the operation of the scientific instrument 1610, to order consumables or replacement parts associated with the scientific instrument 1610, or for other purposes.

The remote computing device 1640 can be a computing device (e.g., in accordance with any of the embodiments of the computing device 400 discussed herein) that is remote from the scientific instrument 1610 and/or from the user local computing device 1620. In one or more embodiments, the remote computing device 1640 can be included in a datacenter or other large-scale server environment. In one or more embodiments, the remote computing device 1640 can include network-attached storage (e.g., as part of the storage device 1604). The remote computing device 1640 can store data generated by the scientific instrument 1610, perform analyses of the data generated by the scientific instrument 1610 (e.g., in accordance with programmed instructions), facilitate communication between the user local computing device 1620 and the scientific instrument 1610, and/or facilitate communication between the service local computing device 1630 and the scientific instrument 1610.

In one or more embodiments, one or more of the elements of the scientific instrument system 1600 illustrated in FIG. 16 can be omitted. Further, in one or more embodiments, multiple ones of various ones of the elements of the scientific instrument system 1600 of FIG. 16 can be present. For example, a scientific instrument system 1600 can include multiple user local computing devices 1620 (e.g., different user local computing devices 1620 associated with different user entities or in different locations). In another example, a scientific instrument system 1600 can include multiple scientific instruments 1610, all in communication with service local computing device 1630 and/or a remote computing device 1640; in such an embodiment, the service local computing device 1630 can monitor these multiple scientific instruments 1610, and the service local computing device 1630 can cause updates or other information can be “broadcast” to multiple scientific instruments 1610 at the same time. Different ones of the scientific instruments 1610 in a scientific instrument system 1600 can be located close to one another (e.g., in the same room) or farther from one another (e.g., on different floors of a building, in different buildings, in different cities, etc.). In one or more embodiments, a scientific instrument 1610 can be connected to an Internet-of-Things (IoT) stack that allows for command and control of the scientific instrument 1610 through a web-based application, a virtual or augmented reality application, a mobile application, and/or a desktop application. Any of these applications can be accessed by a user entity operating the user local computing device 1620 in communication with the scientific instrument 1610 by the intervening remote computing device 1640. In one or more embodiments, a scientific instrument 1610 can be sold by the manufacturer along with one or more associated user local computing devices 1620 as part of a local scientific instrument computing unit 1612.

In one or more embodiments, different ones of the scientific instruments 1610 included in a scientific instrument system 1600 can be different types of scientific instruments 1610; for example, one scientific instrument 1610 can be an EDS device, while another scientific instrument 1610 can be an analysis device that analyzes results of an EDS device. In some such embodiments, the remote computing device 1640 and/or the user local computing device 1620 can combine data from different types of scientific instruments 1610 included in a scientific instrument system 1600.

### Example Operating Environment

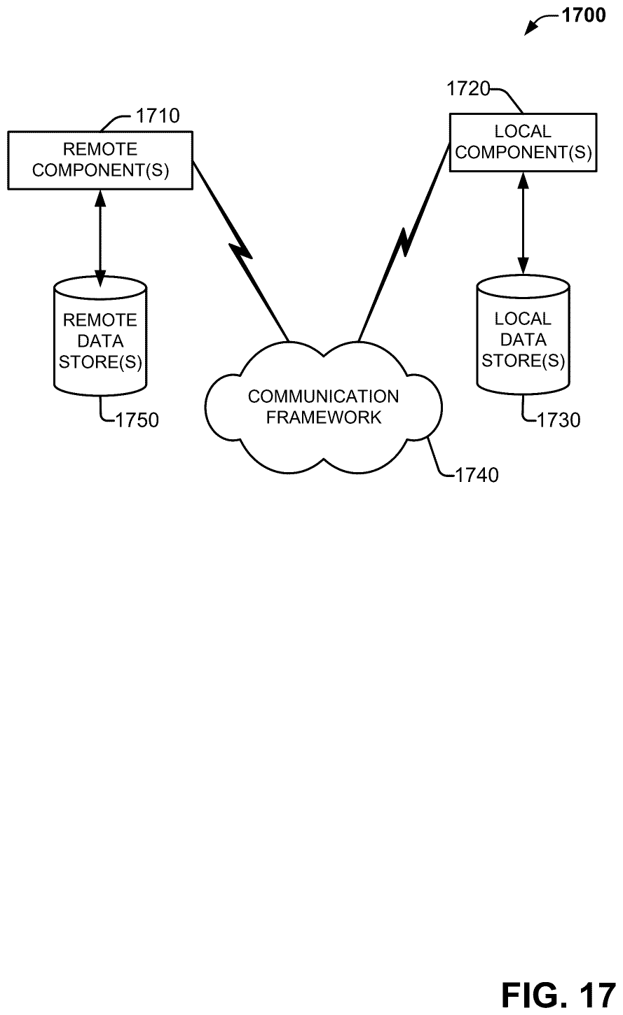

FIG. 17 is a schematic block diagram of an operating environment 1700 with which the described subject matter can interact. The operating environment 1700 comprises one or more remote component(s) 1710. The remote component(s) 1710 can be hardware and/or software (e.g., threads, processes, computing devices). In one or more embodiments, remote component(s) 1710 can be a distributed computer system, connected to a local automatic scaling component and/or programs that use the resources of a distributed computer system, via communication framework 1740. Communication framework 1740 can comprise wired network devices, wireless network devices, mobile devices, wearable devices, radio access network devices, gateway devices, femtocell devices, servers, etc.

The operating environment 1700 also comprises one or more local component(s) 1720. The local component(s) 1720 can be hardware and/or software (e.g., threads, processes, computing devices). In one or more embodiments, local component(s) 1720 can comprise an automatic scaling component and/or programs that communicate/use the remote resources 1710 and 1720, etc., connected to a remotely located distributed computing system via communication framework 1740.

One possible communication between a remote component(s) 1710 and a local component(s) 1720 can be in the form of a data packet adapted to be transmitted between two or more computer processes. Another possible communication between a remote component(s) 1710 and a local component(s) 1720 can be in the form of circuit-switched data adapted to be transmitted between two or more computer processes in radio time slots. The operating environment 1700 comprises a communication framework 1740 that can be employed to facilitate communications between the remote component(s) 1710 and the local component(s) 1720, and can comprise an air interface, e.g., interface of a UMTS network, via an LTE network, etc. Remote component(s) 1710 can be operably connected to one or more remote data store(s) 1750, such as a hard drive, solid state drive, subscriber identity module (SIM) card, electronic SIM (eSIM), device memory, etc., that can be employed to store information on the remote component(s) 1710 side of communication framework 1740. Similarly, local component(s) 1720 can be operably connected to one or more local data store(s) 1730, that can be employed to store information on the local component(s) 1720 side of communication framework 1740.

### Example Computing Environment

In order to provide additional context for various embodiments described herein, FIG. 18 and the following discussion are intended to provide a brief, general description of a suitable computing environment 1800 in which the various embodiments of the embodiment described herein can be implemented. While the embodiments have been described above in the general context of computer-executable instructions that can run on one or more computers, those skilled in the art will recognize that the embodiments can be also implemented in combination with other program modules and/or as a combination of hardware and software.

Generally, program modules include routines, programs, components, data structures, etc., that perform tasks or implement abstract data types. Moreover, the methods can be practiced with other computer system configurations, including single-processor or multiprocessor computer systems, minicomputers, mainframe computers, Internet of Things (IoT) devices, distributed computing systems, as well as personal computers, hand-held computing devices, microprocessor-based or programmable consumer electronics, and the like, each of which can be operatively coupled to one or more associated devices.

The illustrated embodiments of the embodiments herein can also be practiced in distributed computing environments where certain tasks are performed by remote processing devices that are linked through a communications network. In a distributed computing environment, program modules can be located in both local and remote memory storage devices.

Computing devices typically include a variety of media, which can include computer-readable storage media, machine-readable storage media, and/or communications media, which two terms are used herein differently from one another as follows. Computer-readable storage media or machine-readable storage media can be any available storage media that can be accessed by the computer and includes both volatile and nonvolatile media, removable and non-removable media. By way of example, and not limitation, computer-readable storage media or machine-readable storage media can be implemented in connection with any method or technology for storage of information such as computer-readable or machine-readable instructions, program modules, structured data, or unstructured data.

Computer-readable storage media can include, but are not limited to, random access memory (RAM), read only memory (ROM), electrically erasable programmable read only memory (EEPROM), flash memory or other memory technology, compact disk read only memory (CD ROM), digital versatile disk (DVD), Blu-ray disc (BD) or other optical disk storage, magnetic cassettes, magnetic tape, magnetic disk storage or other magnetic storage devices, solid state drives or other solid state storage devices, or other tangible and/or non-transitory media which can be used to store desired information. In this regard, the terms “tangible” or “non-transitory” herein as applied to storage, memory, or computer-readable media, exclude only propagating transitory signals per se as modifiers and do not relinquish rights to all standard storage, memory or computer-readable media that are not only propagating transitory signals per se.

Computer-readable storage media can be accessed by one or more local or remote computing devices, e.g., via access requests, queries, or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and includes any information delivery or transport media. The term “modulated data signal” or signals refers to a signal that has one or more of its characteristics set or changed in such a manner as to encode information in one or more signals. By way of example, and not limitation, communication media include wired media, such as a wired network or direct-wired connection, and wireless media such as acoustic, RF, infrared and other wireless media.

Referring still to FIG. 18, the example computing environment 1800 which can implement one or more embodiments described herein includes a computer 1802, the computer 1802 including a processing unit 1804, a system memory 1806 and a system bus 1808. The system bus 1808 couples system components including, but not limited to, the system memory 1806 to the processing unit 1804. The processing unit 1804 can be any of various commercially available processors. Dual microprocessors and other multi processor architectures can also be employed as the processing unit 1804.

The system bus 1808 can be any of several types of bus structure that can further interconnect to a memory bus (with or without a memory controller), a peripheral bus, and a local bus using any of a variety of commercially available bus architectures. The system memory 1806 includes ROM 1810 and RAM 1812. A basic input/output system (BIOS) can be stored in a non-volatile memory such as ROM, erasable programmable read only memory (EPROM), EEPROM, which BIOS contains the basic routines that help to transfer information between elements within the computer 1802, such as during startup. The RAM 1812 can also include a high-speed RAM such as static RAM for caching data.

The computer 1802 further includes an internal hard disk drive (HDD) 1814 (e.g., EIDE, SATA), and can include one or more external storage devices 1816 (e.g., a magnetic floppy disk drive (FDD) 1816, a memory stick or flash drive reader, a memory card reader, etc.). While the internal HDD 1814 is illustrated as located within the computer 1802, the internal HDD 1814 can also be configured for external use in a suitable chassis (not shown). Additionally, while not shown in computing environment 1800, a solid-state drive (SSD) could be used in addition to, or in place of, an HDD 1814.

Other internal or external storage can include at least one other storage device 1820 with storage media 1822 (e.g., a solid-state storage device, a nonvolatile memory device, and/or an optical disk drive that can read or write from removable media such as a CD-ROM disc, a DVD, a BD, etc.). The external storage 1816 can be facilitated by a network virtual machine. The HDD 1814, external storage device 1816 and storage device (e.g., drive) 1820 can be connected to the system bus 1808 by an HDD interface 1824, an external storage interface 1826 and a drive interface 1828, respectively.

The drives and their associated computer-readable storage media provide nonvolatile storage of data, data structures, computer-executable instructions, and so forth. For the computer 1802, the drives and storage media accommodate the storage of any data in a suitable digital format. Although the description of computer-readable storage media above refers to respective types of storage devices, other types of storage media which are readable by a computer, whether presently existing or developed in the future, could also be used in the example operating environment, and further, that any such storage media can contain computer-executable instructions for performing the methods described herein.

A number of program modules can be stored in the drives and RAM 1812, including an operating system 1830, one or more application programs 1832, other program modules 1834 and program data 1836. All or portions of the operating system, applications, modules, and/or data can also be cached in the RAM 1812. The systems and methods described herein can be implemented utilizing various commercially available operating systems or combinations of operating systems.

Computer 1802 can optionally comprise emulation technologies. For example, a hypervisor (not shown) or other intermediary can emulate a hardware environment for operating system 1830, and the emulated hardware can optionally be different from the hardware illustrated in FIG. 18. In such an embodiment, operating system 1830 can comprise one virtual machine (VM) of multiple VMs hosted at computer 1802. Furthermore, operating system 1830 can provide runtime environments, such as the Java runtime environment or the .NET framework, for applications 1832. Runtime environments are consistent execution environments that allow applications 1832 to run on any operating system that includes the runtime environment. Similarly, operating system 1830 can support containers, and applications 1832 can be in the form of containers, which are lightweight, standalone, executable packages of software that include, e.g., code, runtime, system tools, system libraries and settings for an application.

Further, computer 1802 can be enabled with a security module, such as a trusted processing module (TPM). For instance, with a TPM, boot components hash next in time boot components, and wait for a match of results to secured values, before loading a next boot component. This process can take place at any layer in the code execution stack of computer 1802, e.g., applied at the application execution level or at the operating system (OS) kernel level, thereby enabling security at any level of code execution.

A user entity can enter commands and information into the computer 1802 through one or more wired/wireless input devices, e.g., a keyboard 1838, a touch screen 1840, and a pointing device, such as a mouse 1842. Other input devices (not shown) can include a microphone, an infrared (IR) remote control, a radio frequency (RF) remote control, or other remote control, a joystick, a virtual reality controller and/or virtual reality headset, a game pad, a stylus pen, an image input device, e.g., camera, a gesture sensor input device, a vision movement sensor input device, an emotion or facial detection device, a biometric input device, e.g., fingerprint or iris scanner, or the like. These and other input devices are often connected to the processing unit 1804 through an input device interface 1844 that can be coupled to the system bus 1808, but can be connected by other interfaces, such as a parallel port, an IEEE 1394 serial port, a game port, a USB port, an IR interface, a BLUETOOTH® interface, etc.

A monitor 1846 or other type of display device can also be connected to the system bus 1808 via an interface, such as a video adapter 1848. In addition to the monitor 1846, a computer typically includes other peripheral output devices (not shown), such as speakers, printers, etc.

The computer 1802 can operate in a networked environment using logical connections via wired and/or wireless communications to one or more remote computers, such as a remote computer 1850. The remote computer 1850 can be a workstation, a server computer, a router, a personal computer, portable computer, microprocessor-based entertainment appliance, a peer device or other common network node, and typically includes many or all of the elements described relative to the computer 1802, although, for purposes of brevity, only a memory/storage device 1852 is illustrated. The logical connections depicted include wired/wireless connectivity to a local area network (LAN) 1854 and/or larger networks, e.g., a wide area network (WAN) 1856. Such LAN and WAN networking environments are commonplace in offices and companies, and facilitate enterprise-wide computer networks, such as intranets, all of which can connect to a global communications network, e.g., the Internet.

When used in a LAN networking environment, the computer 1802 can be connected to the local network 1854 through a wired and/or wireless communication network interface or adapter 1858. The adapter 1858 can facilitate wired or wireless communication to the LAN 1854, which can also include a wireless access point (AP) disposed thereon for communicating with the adapter 1858 in a wireless mode.

When used in a WAN networking environment, the computer 1802 can include a modem 1860 or can be connected to a communications server on the WAN 1856 via other means for establishing communications over the WAN 1856, such as by way of the Internet. The modem 1860, which can be internal or external and a wired or wireless device, can be connected to the system bus 1808 via the input device interface 1844. In a networked environment, program modules depicted relative to the computer 1802 or portions thereof, can be stored in the remote memory/storage device 1852. The network connections shown are example and other means of establishing a communications link between the computers can be used.

When used in either a LAN or WAN networking environment, the computer 1802 can access cloud storage systems or other network-based storage systems in addition to, or in place of, external storage devices 1816 as described above. Generally, a connection between the computer 1802 and a cloud storage system can be established over a LAN 1854 or WAN 1856 e.g., by the adapter 1858 or modem 1860, respectively. Upon connecting the computer 1802 to an associated cloud storage system, the external storage interface 1826 can, with the aid of the adapter 1858 and/or modem 1860, manage storage provided by the cloud storage system as it would other types of external storage. For instance, the external storage interface 1826 can be configured to provide access to cloud storage sources as if those sources were physically connected to the computer 1802.

The computer 1802 can be operable to communicate with any wireless devices or entities operatively disposed in wireless communication, e.g., a printer, scanner, desktop and/or portable computer, portable data assistant, communications satellite, any piece of equipment or location associated with a wirelessly detectable tag (e.g., a kiosk, news stand, store shelf, etc.), and telephone. This can include Wireless Fidelity (Wi-Fi) and BLUETOOTH® wireless technologies. Thus, the communication can be a defined structure as with an existing network or simply an ad hoc communication between at least two devices.

### Additional Information

The embodiments described herein can be directed to one or more of a system, a method, an apparatus and/or a computer program product at any possible technical detail level of integration. The computer program product can include a computer readable storage medium (or media) having computer readable program instructions thereon for causing a processor to carry out aspects of the one or more embodiments described herein. The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a superconducting storage device and/or any suitable combination of the foregoing. A non-exhaustive list of more specific examples of the computer readable storage medium can also include the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon and/or any suitable combination of the foregoing. A computer readable storage medium, as used herein, is not to be construed as being transitory signals per se, such as radio waves and/or other freely propagating electromagnetic waves, electromagnetic waves propagating through a waveguide and/or other transmission media (e.g., light pulses passing through a fiber-optic cable), and/or electrical signals transmitted through a wire.

Computer readable program instructions described herein can be downloaded to respective computing/processing devices from a computer readable storage medium and/or to an external computer or external storage device via a network, for example, the Internet, a local area network, a wide area network and/or a wireless network. The network can comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of the one or more embodiments described herein can be assembler instructions, instruction-set-architecture (ISA) instructions, machine instructions, machine dependent instructions, microcode, firmware instructions, state-setting data, configuration data for integrated circuitry, and/or source code and/or object code written in any combination of one or more programming languages, including an object oriented programming language such as Smalltalk, C++ or the like, and/or procedural programming languages, such as the “C” programming language and/or similar programming languages. The computer readable program instructions can execute entirely on a computer, partly on a computer, as a stand-alone software package, partly on a computer and/or partly on a remote computer or entirely on the remote computer and/or server. In the latter scenario, the remote computer can be connected to a computer through any type of network, including a local area network (LAN) and/or a wide area network (WAN), and/or the connection can be made to an external computer (for example, through the Internet using an Internet Service Provider). In one or more embodiments, electronic circuitry including, for example, programmable logic circuitry, field-programmable gate arrays (FPGA) and/or programmable logic arrays (PLA) can execute the computer readable program instructions by utilizing state information of the computer readable program instructions to personalize the electronic circuitry, in order to perform aspects of the one or more embodiments described herein.

Aspects of the one or more embodiments described herein are described with reference to flowchart illustrations and/or block diagrams of methods, apparatus (systems), and computer program products according to one or more embodiments described herein. It will be understood that each block of the flowchart illustrations and/or block diagrams, and combinations of blocks in the flowchart illustrations and/or block diagrams, can be implemented by computer readable program instructions. These computer readable program instructions can be provided to a processor of a general-purpose computer, special purpose computer and/or other programmable data processing apparatus to produce a machine, such that the instructions, which execute via the processor of the computer or other programmable data processing apparatus, can create means for implementing the functions/acts specified in the flowchart and/or block diagram block or blocks. These computer readable program instructions can also be stored in a computer readable storage medium that can direct a computer, a programmable data processing apparatus and/or other devices to function in a particular manner, such that the computer readable storage medium having instructions stored therein can comprise an article of manufacture including instructions which can implement aspects of the function/act specified in the flowchart and/or block diagram block or blocks. The computer readable program instructions can also be loaded onto a computer, other programmable data processing apparatus and/or other device to cause a series of operational acts to be performed on the computer, other programmable apparatus and/or other device to produce a computer implemented process, such that the instructions which execute on the computer, other programmable apparatus and/or other device implement the functions/acts specified in the flowchart and/or block diagram block or blocks.

The flowcharts and block diagrams in the figures illustrate the architecture, functionality and/or operation of possible implementations of systems, computer-implementable methods and/or computer program products according to one or more embodiments described herein. In this regard, each block in the flowchart or block diagrams can represent a module, segment and/or portion of instructions, which comprises one or more executable instructions for implementing the specified logical function. In one or more alternative implementations, the functions noted in the blocks can occur out of the order noted in the Figures. For example, two blocks shown in succession can be executed substantially concurrently, and/or the blocks can sometimes be executed in the reverse order, depending upon the functionality involved. It will also be noted that each block of the block diagrams and/or flowchart illustration, and/or combinations of blocks in the block diagrams and/or flowchart illustration, can be implemented by special purpose hardware-based systems that can perform the specified functions and/or acts and/or carry out one or more combinations of special purpose hardware and/or computer instructions.

While the subject matter has been described above in the general context of computer-executable instructions of a computer program product that runs on a computer and/or computers, those skilled in the art will recognize that the one or more embodiments herein also can be implemented at least partially in parallel with one or more other program modules. Generally, program modules include routines, programs, components and/or data structures that perform particular tasks and/or implement particular abstract data types. Moreover, the aforedescribed computer-implemented methods can be practiced with other computer system configurations, including single-processor and/or multiprocessor computer systems, mini-computing devices, mainframe computers, as well as computers, hand-held computing devices (e.g., PDA, phone), and/or microprocessor-based or programmable consumer and/or industrial electronics. The illustrated aspects can also be practiced in distributed computing environments in which tasks are performed by remote processing devices that are linked through a communications network. However, one or more, if not all aspects of the one or more embodiments described herein can be practiced on stand-alone computers. In a distributed computing environment, program modules can be located in both local and remote memory storage devices.

As used in this application, the terms “component,” “system,” “platform” and/or “interface” can refer to and/or can include a computer-related entity or an entity related to an operational machine with one or more specific functionalities. The entities described herein can be either hardware, a combination of hardware and software, software, or software in execution. For example, a component can be, but is not limited to being, a process running on a processor, a processor, an object, an executable, a thread of execution, a program and/or a computer. By way of illustration, both an application running on a server and the server can be a component. One or more components can reside within a process and/or thread of execution and a component can be localized on one computer and/or distributed between two or more computers. In another example, respective components can execute from various computer readable media having various data structures stored thereon. The components can communicate via local and/or remote processes such as in accordance with a signal having one or more data packets (e.g., data from one component interacting with another component in a local system, distributed system and/or across a network such as the Internet with other systems via the signal). As another example, a component can be an apparatus with specific functionality provided by mechanical parts operated by electric or electronic circuitry, which is operated by a software and/or firmware application executed by a processor. In such a case, the processor can be internal and/or external to the apparatus and can execute at least a part of the software and/or firmware application. As yet another example, a component can be an apparatus that provides specific functionality through electronic components without mechanical parts, where the electronic components can include a processor and/or other means to execute software and/or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter described herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

As it is employed in the subject specification, the term “processor” can refer to substantially any computing processing unit and/or device comprising, but not limited to, single-core processors; single-processors with software multithread execution capability; multi-core processors; multi-core processors with software multithread execution capability; multi-core processors with hardware multithread technology; parallel platforms; and/or parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, and/or any combination thereof designed to perform the functions described herein. Further, processors can exploit nano-scale architectures such as, but not limited to, molecular and quantum-dot based transistors, switches and/or gates, in order to optimize space usage and/or to enhance performance of related equipment. A processor can be implemented as a combination of computing processing units.

Herein, terms such as “store,” “storage,” “data store,” “data storage,” “database,” and substantially any other information storage component relevant to operation and functionality of a component are utilized to refer to “memory components,” entities embodied in a “memory,” or components comprising a memory. Memory and/or memory components described herein can be either volatile memory or nonvolatile memory or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory and/or nonvolatile random-access memory (RAM) (e.g., ferroelectric RAM (FeRAM). Volatile memory can include RAM, which can act as external cache memory, for example. By way of illustration and not limitation, RAM can be available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM) and/or Rambus dynamic RAM (RDRAM). Additionally, the described memory components of systems and/or computer-implemented methods herein are intended to include, without being limited to including, these and/or any other suitable types of memory.

What has been described above includes mere examples of systems and computer-implemented methods. It is, of course, not possible to describe every conceivable combination of components and/or computer-implemented methods for purposes of describing the one or more embodiments, but one of ordinary skill in the art can recognize that many further combinations and/or permutations of the one or more embodiments are possible. Furthermore, to the extent that the terms “includes,” “has,” “possesses,” and the like are used in the detailed description, claims, appendices and/or drawings such terms are intended to be inclusive in a manner similar to the term “comprising” as “comprising” is interpreted when employed as a transitional word in a claim.

The descriptions of the various embodiments can use the phrases “an embodiment,” “various embodiments,” “one or more embodiments” and/or “some embodiments,” each of which can refer to one or more of the same or different embodiments.

The descriptions of the various embodiments have been presented for purposes of illustration but are not intended to be exhaustive or limited to the embodiments described herein. Many modifications and variations will be apparent to those of ordinary skill in the art without departing from the scope and spirit of the described embodiments. The terminology used herein was chosen to best explain the principles of the embodiments, the practical application and/or technical improvement over technologies found in the marketplace, and/or to enable others of ordinary skill in the art to understand the embodiments described herein.

What is claimed is:

1. A system, comprising:
a memory that stores computer executable components; and
a processor that executes the computer executable components stored in the memory, wherein the computer executable components comprise:
a rendering engine component that renders a virtual environment comprising a three-dimensional simulation of a simulated imaging device comprising a simulated chamber having a simulated object for analysis being rendered therein; and
a simulating component that generates simulation data corresponding to a directed interaction comprising a three-dimensional modification of the simulated object.

2. The system of claim 1, wherein the computer executable components further comprise:
an interfacing component that maps a physical aspect of physical hardware of a non-virtually-simulated imaging device to a corresponding rendered aspect of the three-dimensional simulation.

3. The system of claim 1, wherein the system further comprises:
an imaging device automation and control component that controls automation of a physical hardware of a non-virtually-simulated imaging device,
wherein the imaging device automation and control component also directs, based on the simulation data, a second digital display corresponding to the three-dimensional simulation.

4. The system of claim 3, wherein the imaging device automation and control component interprets the simulation data as physical hardware feedback data of the physical hardware of the non-virtually-simulated imaging device.

5. The system of claim 1, wherein the computer executable components further comprise:
a notifying component that generates a notification of a failure of a simulated workflow within the virtual environment or of a simulated touch interaction with a simulated element within the simulated chamber.

6. The system of claim 1, wherein the computer executable components further comprise:
a parameterizing component that simulates a change to an imaging device parameter changing a state of the virtual environment to correspond to a selectable change of state of a chamber of a non-virtually-simulated imaging device.

7. The system of claim 1, wherein the computer executable components further comprise:
an interfacing component that, based on process flow data corresponding to a process flow being performed at physical hardware of a non-virtually-simulated imaging device, directs, within the virtual environment, rendering of a simulated test of a subsequent action to be performed at the physical hardware of a non-virtually-simulated imaging device.

8. The system of claim 1, wherein the computer executable components further comprise:
an interfacing component that obtains feedback from a set of controls and that directs rendering of the digital display based on the feedback.

9. A computer-implemented method, comprising:
rendering, by a system operatively coupled to a processor, a virtual environment comprising a three-dimensional simulation of a simulated imaging device comprising a simulated chamber having a simulated object for analysis being rendered therein; and
generating, by the system, simulation data corresponding to a directed interaction comprising a three-dimensional modification of the simulated object.

10. The computer-implemented method of claim 9, further comprising:
mapping, by the system, a physical aspect of physical hardware of a non-virtually-simulated imaging device to a corresponding rendered aspect of the three-dimensional simulation.

11. The computer-implemented method of claim 9, further comprising:
controlling, by the system, automation of a physical hardware of a non-virtually-simulated imaging device; and
directing, by the system, based on the simulation data, a second digital display corresponding to the three-dimensional simulation.

12. The computer-implemented method of claim 11, further comprising:
interpreting, by the system, the simulation data as physical hardware feedback data of the physical hardware of the non-virtually-simulated imaging device.

13. The computer-implemented method of claim 9, further comprising:
generating, by the system, a notification of a failure of a simulated workflow within the virtual environment or of a simulated touch interaction with a simulated element within the simulated chamber.

14. The computer-implemented method of claim 9, further comprising:
simulating, by the system, a change to an imaging device parameter changing a state of the virtual environment to correspond to a selectable change of state of a chamber of a non-virtually-simulated imaging device.

15. A computer program product facilitating a process for imaging device virtual simulation, the computer program product comprising a computer readable storage medium having program instructions embodied therewith, and the program instructions executable by a processor to cause the processor to:
render, by the processor, a virtual environment comprising a three-dimensional simulation of a simulated object within a simulated chamber of a simulated imaging device; and
generate, by the processor, simulation data corresponding to a directed interaction comprising a three-dimensional modification of the simulated object.

16. The computer program product of claim 15, wherein the program instructions are further executable by the processor to cause the processor to:
map, by the processor, a physical aspect of physical hardware of a non-virtually-simulated imaging device to a corresponding rendered aspect of the three-dimensional simulation.

17. The computer program product of claim 15, wherein the program instructions executable by the processor to cause the processor to identify further cause the processor to:
control, by the processor, automation of a physical hardware of a non-virtually-simulated imaging device; and
direct, by the processor, based on the simulation data, a second digital display corresponding to the three-dimensional simulation.

18. The computer program product of claim 17, wherein the program instructions are further executable by the processor to cause the processor to:
interpret, by the processor, the simulation data as physical hardware feedback data of the physical hardware of the non-virtually-simulated imaging device.

19. The computer program product of claim 15, wherein the program instructions are further executable by the processor to cause the processor to:
generate, by the processor, a notification of a failure of a simulated workflow within the virtual environment or of a simulated touch interaction with a simulated element within the simulated chamber.

20. The computer program product of claim 15, wherein the program instructions are further executable by the processor to cause the processor to:
simulate, by the processor, a change to an imaging device parameter changing a state of the virtual environment to correspond to a selectable change of state of a chamber of a non-virtually-simulated imaging device.
